(19) United States
(12) Patent Application Publication
(10) Pub. No.: US 2023/0363280 A1
(43) Pub. Date: Nov. 9, 2023

(54) PIEZOELECTRIC ELEMENT, PIEZOELECTRIC DEVICE, AND METHOD FOR MANUFACTURING PIEZOELECTRIC ELEMENT

(71) Applicant: DENSO CORPORATION, Kariya-city (JP)

(72) Inventors: Minekazu SAKAI, Kariya-city (JP); Kazuaki MAWATARI, Kariya-city (JP); Yuji KOYAMA, Kariya-city (JP); Masaaki TANAKA, Kariya-city (JP); Tomoya JOMORI, Kariya-city (JP); Yuhei SHIMIZU, Kariya-city (JP)

(21) Appl. No.: 18/356,487

(22) Filed: Jul. 21, 2023

Related U.S. Application Data
(63) Continuation of application No. PCT/JP2022/003806, filed on Feb. 1, 2022.

(30) Foreign Application Priority Data
Feb. 3, 2021 (JP) 2021-016148

(51) Int. Cl. H10N 30/00; H10N 30/853; H10N 30/074

(52) U.S. Cl. CPC H10N 30/10516; H10N 30/853; H10N 30/074

(57) ABSTRACT

A piezoelectric element includes a support and a vibration unit disposed on the support. The vibration unit includes a piezoelectric film and an electrode film connected to the piezoelectric film to extract charges generated by deformation of the piezoelectric film. The vibration unit has a support region supported on the support, and a vibration region connected to the support region and floating from the support. The vibration unit outputs a pressure detection signal based on the charges. The vibration region includes a plurality of slits extending from a support region side toward a center of the vibration region and is in a state of being supported at both ends with respect to the support region.

### CROSS REFERENCE TO RELATED APPLICATIONS

The present application is a continuation application of International Patent Application No. PCT/JP2022/003806 filed on Feb. 1, 2022, which designated the U.S. and claims the benefit of priority from Japanese Patent Application No. 2021-016148 filed on Feb. 3, 2021. The entire disclosures of all of the above applications are incorporated herein by reference.

### TECHNICAL FIELD

The present disclosure relates to a piezoelectric element having a vibration region, a piezoelectric device, and a method for manufacturing a piezoelectric element.

### BACKGROUND

A piezoelectric element having a vibration region has conventionally been proposed. For example, the vibration region of the piezoelectric element includes a piezoelectric film and an electrode film connected to the piezoelectric film. The vibration region is cantilevered. In such a piezoelectric element, acoustic pressure (hereinafter, also simply referred to as sound pressure) or the like vibrates the vibration region, causing the piezoelectric film to deform and generate charges in the piezoelectric film. The sound pressure applied to the vibration region is detected by extracting the charges generated in the piezoelectric film via the electrode film.

### SUMMARY

The present disclosure describes a piezoelectric element, a piezoelectric device, and a method for manufacturing a piezoelectric element. According to an aspect, a piezoelectric element includes a support and a vibration unit disposed on the support. The vibration unit includes a piezoelectric film, and an electrode film connected to the piezoelectric film to extract charges generated by a deformation of the piezoelectric film. The vibration unit has a support region supported by the support, and a vibration region connected to the support region and floating from the support. The vibration unit is configured to output a pressure detection signal based on the charges. The vibration region includes a plurality of slits extending from a support region side toward a center of the vibration region, and the vibration region is supported at both ends with respect to the support region.

### BRIEF DESCRIPTION OF DRAWINGS

FIG. 1A is a cross-sectional view of a piezoelectric element according to a first embodiment.

FIG. 1B is a cross-sectional view of the piezoelectric element according to the first embodiment.

FIG. 1C is a cross-sectional view of the piezoelectric element according to the first embodiment.

FIG. 2A is a plan view of the piezoelectric element according to the first embodiment.

FIG. 2B is a plan view of an electrode film formed in a first region according to the first embodiment.

FIG. 3 is a schematic circuit diagram of the piezoelectric element according to the first embodiment.

FIG. 4A shows a method for manufacturing the piezoelectric element illustrated in FIG. 1C.

FIG. 4B shows the method for manufacturing a piezoelectric element following FIG. 4A.

FIG. 4C shows the method for manufacturing a piezoelectric element following FIG. 4B.

FIG. 5 is a cross-sectional view of the piezoelectric device according to the first embodiment.

FIG. 6 is a diagram showing a relationship between a coupling length and a resonance frequency of a piezoelectric element.

FIG. 7 is a diagram showing a relationship between a frequency applied to a vibration region and an output signal.

FIG. 8 is a diagram showing a relationship between a coupling length and a generated stress ratio.

FIG. 9 is a diagram showing a relationship between sound pressure and an output signal.

FIG. 10A is a plan view of a piezoelectric element according to a modification of the first embodiment.

FIG. 10B is a plan view of a piezoelectric element according to a modification of the first embodiment.

FIG. 11A is a plan view of a vibration region according to a modification of the first embodiment.

FIG. 11B is a plan view of a vibration region according to a modification of the first embodiment.

FIG. 11C is a plan view of a vibration region according to a modification of the first embodiment.

FIG. 11D is a plan view of a vibration region according to a modification of the first embodiment.

FIG. 11E is a plan view of a vibration region according to a modification of the first embodiment.

FIG. 11F is a plan view of a vibration region according to a modification of the first embodiment.

FIG. 11G is a plan view of a vibration region according to a modification of the first embodiment.

FIG. 12 is a plan view of an electrode film formed in a first region according to a modification of the first embodiment.

FIG. 13 is a schematic circuit diagram of a piezoelectric element including the electrode film illustrated in FIG. 12.

FIG. 14 is a plan view of a piezoelectric element according to a second embodiment.

FIG. 15 is a schematic diagram of a vibration region described in a third embodiment.

FIG. 16 is a schematic diagram illustrating a magnitude of a bending moment in a vibration region.

FIG. 17 is a diagram illustrating stress distribution in a vibration region.

FIG. 18 is a plan view of a piezoelectric element according to the third embodiment.

FIG. 19 is a schematic circuit diagram of the piezoelectric element illustrated in FIG. 18.

FIG. 20 is a cross-sectional view of a piezoelectric element according to a fourth embodiment.

FIG. 21 is a plan view of the piezoelectric element illustrated in FIG. 20.

FIG. 22 is a cross-sectional view of a piezoelectric element according to a fifth embodiment.

FIG. 23 is a plan view of the piezoelectric element illustrated in FIG. 22.

FIG. 24A is a plan view of a piezoelectric element according to a sixth embodiment.

FIG. 24B is a plan view of an electrode film formed in a first region according to the sixth embodiment.

FIG. 25 is a schematic circuit diagram of a piezoelectric element according to the sixth embodiment.

FIG. 26 is a cross-sectional view of the piezoelectric element according to the sixth embodiment.

FIG. 27 is a plan view of a piezoelectric element according to a modification of the sixth embodiment.

FIG. 28 is a plan view of an electrode film formed in a first region according to a modification of the sixth embodiment.

FIG. 29 is a schematic circuit diagram of a piezoelectric element according to a modification of the sixth embodiment.

FIG. 30 is a plan view of a piezoelectric element according to a seventh embodiment.

FIG. 31 is a cross-sectional view of a piezoelectric device according to the seventh embodiment.

FIG. 32 is a schematic cross-sectional view of a piezoelectric device according to an eighth embodiment.

FIG. 33 is a diagram showing a relationship between the slit width, the slit length, and acoustic resistance when the thickness of a vibration region is constant.

FIG. 34 is a diagram showing a relationship between the thickness of a vibration region, the slit length, and acoustic resistance when the slit width is constant.

FIG. 35 is a diagram showing a relationship between a slit length and an acoustic resistance ratio.

FIG. 36 is a cross-sectional view of a slit of a piezoelectric element according to a ninth embodiment.

FIG. 37 is a diagram showing a relationship between a slit width on one surface side and acoustic resistance.

FIG. 38A is a cross-sectional view of a slit of a piezoelectric element according to a modification of the ninth embodiment.

FIG. 38B is a cross-sectional view of a slit of a piezoelectric element according to a modification of the ninth embodiment.

FIG. 38C is a cross-sectional view of a slit of a piezoelectric element according to a modification of the ninth embodiment.

FIG. 39 is a plan view illustrating a positional relationship between a piezoelectric element and a bonding member according to a tenth embodiment.

FIG. 40A is a plan view illustrating a positional relationship between a piezoelectric element and a bonding member according to a modification of the tenth embodiment.

FIG. 40B is a plan view illustrating a positional relationship between a piezoelectric element and a bonding member according to a modification of the tenth embodiment.

FIG. 41A is a plan view illustrating a positional relationship between a piezoelectric element and a bonding member according to a modification of the tenth embodiment.

FIG. 41B is a plan view illustrating a positional relationship between a piezoelectric element and a bonding member according to a modification of the tenth embodiment.

FIG. 41C is a plan view illustrating a positional relationship between a piezoelectric element and a bonding member according to a modification of the tenth embodiment.

FIG. 42 is a cross-sectional view of a piezoelectric device according to an eleventh embodiment.

FIG. 43 is a cross-sectional view of a piezoelectric element according to a twelfth embodiment.

FIG. 44A is a cross-sectional view illustrating a process for manufacturing the piezoelectric element illustrated in FIG. 43.

FIG. 44B is a cross-sectional view illustrating a process for manufacturing the piezoelectric element following FIG. 44A.

FIG. 44C is a cross-sectional view illustrating a process for manufacturing the piezoelectric element following FIG. 44B.

FIG. 45 is a schematic diagram of a portion where a slit is formed in the manufacturing step of FIG. 44C.

FIG. 46 is a diagram illustrating a relationship between the frequency, the sensitivity, and the effective width.

FIG. 47 is a diagram illustrating a relationship between a film thickness of an etching mask material with respect to a film thickness of a piezoelectric film and an angle to be formed.

FIG. 48 is a cross-sectional view of a piezoelectric device according to another embodiment.

### DETAILED DESCRIPTION

In piezoelectric elements, there is a demand for improving the detection accuracy. The present disclosure provides a piezoelectric element, a piezoelectric device, and a method for manufacturing a piezoelectric element, which can improve the detection accuracy.

According to an aspect of the present disclosure, a piezoelectric element includes a support and a vibration unit disposed on the support. The vibration unit includes a piezoelectric film and an electrode film that is connected to the piezoelectric film to extract charges generated by a deformation of the piezoelectric film. The vibration unit has a support region supported by the support, and a vibration region connected to the support region and floating from the support. The vibration unit is configured to output a pressure detection signal based on the charges. The vibration region includes a plurality of slits extending from a support region side toward a center of the vibration region, and is supported at both ends with respect to the support region.

According to this, the resonance frequency can be increased as compared with the case where the vibration region is cantilevered. Thus, the frequency at which the detection sensitivity can be maintained can be widened, and the detection accuracy can be improved.

According to another aspect of the present disclosure, a piezoelectric device includes the above-described piezoelectric element and a casing that includes a mounted member on which the piezoelectric element is mounted and a lid fixed to the mounted member with the piezoelectric element being accommodated. The casing is formed with a through hole communicating with an outside and through which the pressure is introduced.

According to this, because the piezoelectric element capable of increasing the resonance frequency is included, the frequency at which the detection sensitivity can be maintained can be widened and the detection accuracy can be improved.

According to another aspect of the present disclosure, a method related to the piezoelectric element includes: providing the support; forming the piezoelectric film and the electrode film on the support; disposing an etching mask material on the piezoelectric film and the electrode film and forming an opening in the etching mask material to expose a portion of the piezoelectric film where each of the slits is to be formed; forming the slits by performing etching with the etching mask material used as a mask so that each of the slits penetrates the piezoelectric film, reaches the support and defines a vibration region constituent part having a tapered portion where a width of a side surface exposed from the slit is decreased from one surface side, which is on a side opposite from the support, toward another surface side opposite to the one surface; and forming a recess from the opposite side of the support from the piezoelectric film to cause the vibration region constituent part to float, thereby to constitute the vibration unit including the vibration region. Further, in the forming of the piezoelectric film and the electrode film, the piezoelectric film and the electrode film are formed such that only the piezoelectric film is exposed from the side surface when the vibration region constituent part is formed, and in the forming of the slits, the slits are formed in which an angle formed by a side surface constituting the tapered portion and the surface parallel to the one surface is 39 to 81°.

According to this, a piezoelectric element capable of increasing the resonance frequency can be manufactured. In addition, deterioration in the processability when the slit is formed can be prevented by setting the angle to be formed to 39 to 81°.

Hereinafter, embodiments of the present disclosure will be described with reference to the drawings. In the following embodiments, the same or equivalent portions are denoted by the same reference numerals.

### First Embodiment

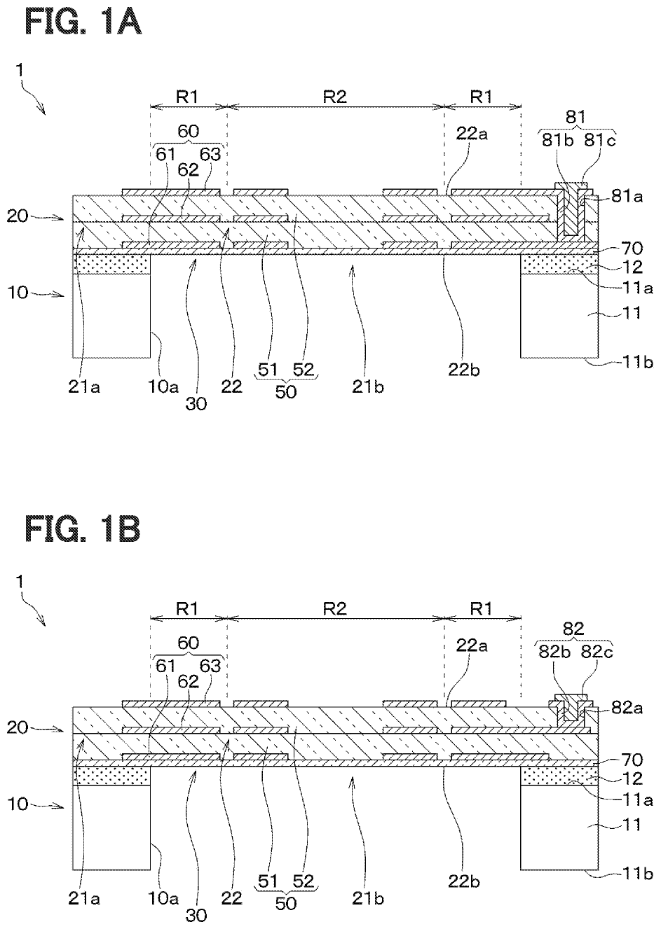

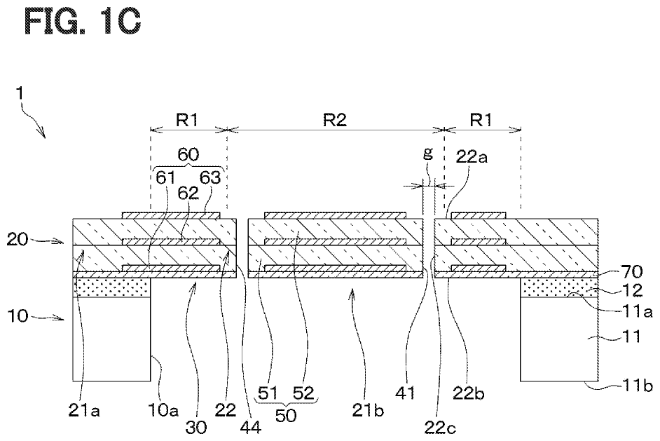

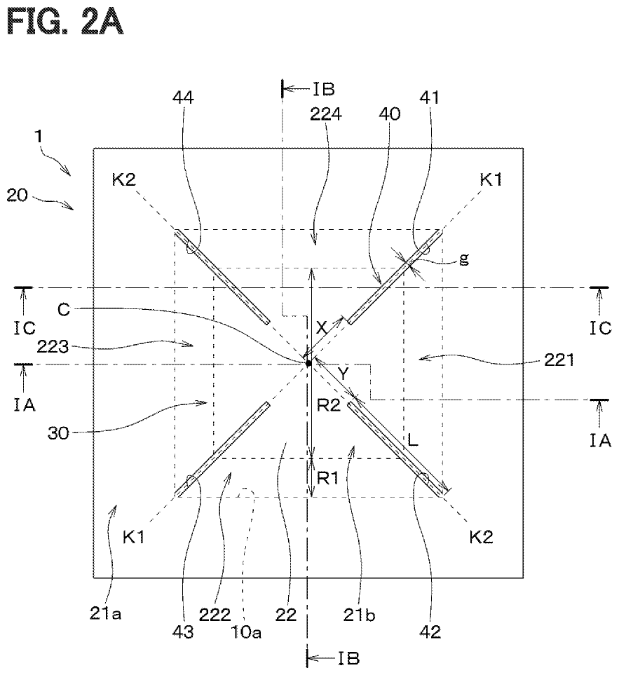

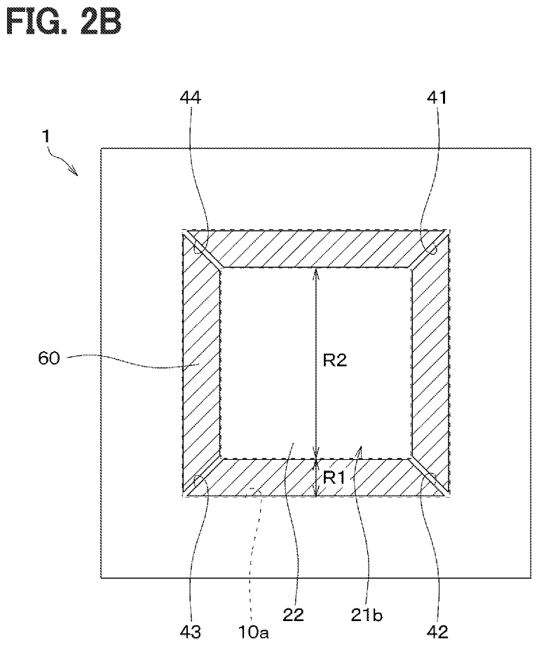

A piezoelectric element 1 according to a first embodiment will be described with reference to FIGS. 1A, 1B, 1C, 2A, and 2B. The piezoelectric element 1 of the present embodiment may be suitable for use as, for example, a microphone. FIG. 1A corresponds to a cross-sectional view taken along line IA-IA in FIG. 2A, FIG. 1B corresponds to a cross-sectional view taken along line IB-IB in FIG. 2A, and FIG. 1C corresponds to a cross-sectional view taken along line IC-IC in FIG. 2A. In FIG. 2A, a first electrode unit 81, a second electrode unit 82, and the like, which will be described later, are omitted. The first electrode unit 81, the second electrode unit 82, and the like are appropriately omitted in each drawing corresponding to FIG. 2A described later.

The piezoelectric element 1 of the present embodiment includes a support 10 and a vibration unit 20, and has a rectangular planar shape. The support 10 includes a support substrate 11 having one surface 11a and another surface 11b, and an insulating film 12 formed on the one surface 11 a of the support substrate 11. The support substrate 11 is formed of a silicon substrate or the like, and the insulating film 12 is formed of an oxide film or the like, for example.

The vibration unit 20 constitutes a sensing unit 30 that outputs a pressure detection signal corresponding to sound pressure or the like as pressure, and is disposed on the support 10. The support 10 is formed with a recess 10a for causing an inner edge side of the vibration unit 20 to float. Thus, the vibration unit 20 has a support region 21a disposed on the support 10 and a floating region 21b connected to the support region 21a and floating above the recess 10a. In the recess 10a of the present embodiment, the shape of the open end on the vibration unit 20 side (hereinafter, also simply referred to as an open end of the recess 10a) has a rectangular shape in a plane. Thus, the entire floating region 21b has a rectangular shape in a plane.

The floating region 21b is formed with a slit 40 penetrating the floating region 21b in a thickness direction. In the present embodiment, first to fourth slits 41 to 44 are formed in the floating region 21b. The first to fourth slits 41 to 44 is extended from the corners of the floating region 21b having a rectangular shape in a plane toward a center C of the floating region 21b. The first to fourth slits 41 to 44 are formed so as not to reach the center C. In other words, the first to fourth slits 41 to 44 are formed to terminate on the support region 21a side from the center C. That is, the first to fourth slits 41 to 44 are formed so as not to divide the floating region 21b.

In the present embodiment, the first to fourth slits 41 to 44 are formed such that their slit lengths L along an extending direction are equal to each other. Further, the first to fourth slits 41 to 44 of the present embodiment have a constant slit width g along a thickness direction of the vibration region 22. Such a floating region 21b constitutes the vibration region 22, and the vibration region 22 is in a state of being supported at both ends by the support region 21a.

The slit width g of the first to fourth slits 41 to 44 is a length in a direction orthogonal to the extending direction of the first to fourth slits 41 to 44 and along a plane direction of the vibration region 22. In other words, the slit width g of the first to fourth slits 41 to 44 is an interval between side surfaces 22c of the vibration region 22 exposed by the first to fourth slits 41 to 44.

Hereinafter, the surface of the vibration region 22 on the opposite side from the support 10 is defined as one surface 22a of the vibration region 22, and the surface of the vibration region 22 on the support 10 side is defined as another surface 22b of the vibration region 22. A surface of the vibration region 22 exposed from the first to fourth slits 41 to 44 is defined as the side surface 22c of the vibration region 22. Hereinafter, in a normal direction with respect to the one surface 22a of the vibration region 22, a region surrounded by one side forming the outer shape of the vibration region 22 and by virtual lines K1 and K2 extending along the slits 41 to 44 is referred to as first to fourth vibration regions 221 to 224. Hereinafter, the normal direction with respect to the one surface 22a of the vibration region 22 is also simply referred to as a normal direction. “In the normal direction with respect to the one surface 22a of the vibration region 22” may also be referred to as “when viewed from the normal direction with respect to the one surface 22a of the vibration region 22”.

In the present embodiment, a virtual line extending along the first slit 41 and the third slit 43 is defined as the virtual line K1, and a virtual line extending along the second slit 42 and the fourth slit 44 is defined as the virtual line K2. In the normal direction, a region included between the first slit 41 and the second slit 42 and surrounded by the virtual line K1 and the virtual line K2 in the vibration region 22 is defined as the first vibration region 221. In the normal direction, a region included between the second slit 42 and the third slit 43 and surrounded by the virtual line K1 and the virtual line K2 in the vibration region 22 is defined as the second vibration region 222. In the normal direction, a region included between the third slit 43 and the fourth slit 44 and surrounded by the virtual line K1 and the virtual line K2 in the vibration region 22 is defined as the third vibration region 223. In the normal direction, a region included between the fourth slit 44 and the first slit 41 and surrounded by the virtual line K1 and the virtual line K2 in the vibration region 22 is defined as the fourth vibration region 224. The vibration region 22 of the present embodiment is formed by integrating the first to fourth vibration regions 221 to 224.

The vibration unit 20 includes a piezoelectric film 50 and an electrode film 60 connected to the piezoelectric film 50. Specifically, the piezoelectric film 50 includes a lower piezoelectric film 51 and an upper piezoelectric film 52 stacked on the lower piezoelectric film 51. The electrode film 60 includes a lower electrode film 61 disposed below the lower piezoelectric film 51, an intermediate electrode film 62 disposed between the lower piezoelectric film 51 and the upper piezoelectric film 52, and an upper electrode film 63 disposed on the upper piezoelectric film 52. That is, the vibration unit 20 has a bimorph structure in which the lower piezoelectric film 51 is sandwiched between the lower electrode film 61 and the intermediate electrode film 62, and the upper piezoelectric film 52 is sandwiched between the intermediate electrode film 62 and the upper electrode film 63.

The lower piezoelectric film 51 and the upper piezoelectric film 52 are made of lead-free piezoelectric ceramic or the like, such as scandium aluminum nitride (ScAlN) and aluminum nitride (AlN). The lower electrode film 61, the intermediate electrode film 62, and the upper electrode film 63 are made of molybdenum, copper, platinum, platinum, titanium, or the like.

Further, the vibration unit 20 of the present embodiment includes a base film 70 on which the lower piezoelectric film 51 and the lower electrode film 61 are disposed. That is, the piezoelectric film 50 and the electrode film 60 are disposed on the support 10, with the base film 70 interposed between the piezoelectric film 50 and the electrode film 60. The base film 70 is not necessarily required, but is provided to facilitate crystal growth when the lower piezoelectric film 51 and the like are formed. In the present embodiment, the base film 70 is made of aluminum nitride or the like. The piezoelectric film 50 has a thickness of about 1 μm, and the base film 70 has a thickness of about several tens nm. That is, the base film 70 is extremely thin with respect to the piezoelectric film 50.

In each vibration region 22 of the present embodiment, a portion on the support region 21a side that becomes a fixed end when the vibration region 22 vibrates is a first region R1, and a portion on the center C side is a second region R2. The lower electrode film 61, the intermediate electrode film 62, and the upper electrode film 63 are formed in both the first region R1 and the second region R2. However, the lower electrode film 61, the intermediate electrode film 62, and the upper electrode film 63 formed in the first region R1 are separated from and insulated from the lower electrode film 61, the intermediate electrode film 62, and the upper electrode film 63 formed in the second region R2. The lower electrode film 61, the intermediate electrode film 62, and the upper electrode film 63 formed in the first region R1 are appropriately extended to the support region 21a.

In the present embodiment, the lower electrode film 61, the intermediate electrode film 62, and the upper electrode film 63 are formed so as not to reach the first to fourth slits 41 to 44. That is, the lower electrode film 61, the intermediate electrode film 62, and the upper electrode film 63 are formed to terminate on the inner side of the side surface 22c exposed from the first to fourth slits 41 to 44 in the vibration region 22. In other words, the lower electrode film 61, the intermediate electrode film 62, and the upper electrode film 63 are disposed on the inner side of the first to fourth slits 41 to 44 in the normal direction. Thus, the side surface 22c of the vibration region 22 is formed of the lower piezoelectric film 51, the upper piezoelectric film 52, and the base film 70.

The support region 21a of the vibration unit 20 is formed with the first electrode unit 81 electrically connected to the lower electrode film 61 and the upper electrode film 63 formed in the first region R1, and the second electrode unit 82 electrically connected to the intermediate electrode film 62 formed in the first region R1. As described above, in FIG. 2A, the first electrode unit 81 and the second electrode unit 82 are omitted.

The first electrode unit 81 is formed in a hole portion 81a that penetrates the upper electrode film 63, the upper piezoelectric film 52, and the lower piezoelectric film 51. The first electrode unit 81 includes a through electrode 81b electrically connected to the lower electrode film 61 and the upper electrode film 63. In the present embodiment, the through electrode 81b is electrically connected to the lower electrode film 61 and the upper electrode film 63 formed in the first vibration region 221. The first electrode unit 81 includes a pad portion 81c formed on the through electrode 81b and electrically connected to the through electrode 81b.

The second electrode unit 82 is formed in a hole portion 82a that penetrates the upper piezoelectric film 52 to expose the intermediate electrode film 62. The second electrode unit 82 includes a through electrode 82b electrically connected to the intermediate electrode film 62. In the present embodiment, the through electrode 82b is electrically connected to the intermediate electrode film 62 formed in the fourth vibration region 224. The second electrode unit 82 has a pad portion 82c formed on the through electrode 82b and electrically connected to the through electrode 82b.

Similarly to the electrode film 60, the first electrode unit 81 and the second electrode unit 82 are made of molybdenum, copper, platinum, titanium, aluminum, or the like. The lower electrode film 61, the intermediate electrode film 62, and the upper electrode film 63 formed in the second region R2 are not electrically connected to the electrode units 81 and 82, and are in a floating state. Thus, the lower electrode film 61, the intermediate electrode film 62, and the upper electrode film 63 formed in the second region R2 are not necessarily required, but they are provided in the present embodiment to protect portions of the lower piezoelectric film 51 and the upper piezoelectric film 52 positioned in the second region R2.

The lower electrode film 61, the intermediate electrode film 62, and the upper electrode film 63 formed in the first region R1 are divided by the first to fourth vibration regions 221 to 224. That is, the lower electrode film 61, the intermediate electrode film 62, and the upper electrode film 63 formed in the first region R1 are not formed in such a manner as to straddle the first to fourth vibration regions 221 to 224. The lower electrode film 61, the intermediate electrode film 62, and the upper electrode film 63 formed in the first region R1 of each of the vibration regions 221 to 224 are connected via a wiring film (not illustrated) or the like.

As illustrated in FIG. 2B, the lower electrode film 61, the intermediate electrode film 62, and the upper electrode film 63 of the present embodiment are formed such that the outer shape of the portion formed in the first region R1 is substantially equal to the outer shape of the vibration region 22, and in the present embodiment, the lower electrode film 61, the intermediate electrode film 62, and the upper electrode film 63 have a rectangular shape in a plane. The lower electrode film 61, the intermediate electrode film 62, and the upper electrode film 63 are divided by the first to fourth vibration regions 221 to 224 as described above. For this reason, the outer shape of the portion formed in the first region R1 of the lower electrode film 61, the intermediate electrode film 62, and the upper electrode film 63 described here is a shape formed by the outline of the portion positioned in the first region R1 in the lower electrode film 61, the intermediate electrode film 62, and the upper electrode film 63 and an extension line of the outline. FIG. 2B is not a cross-sectional view, but the electrode film 60 formed in the first region R1 is hatched for easy understanding. The electrode film 60 is illustrated in FIG. 2B. The lower electrode film 61, the intermediate electrode film 62, and the upper electrode film 63 serving as the electrode film 60 have the same shape as the electrode film 60 in FIG. 2B in the first region R1.

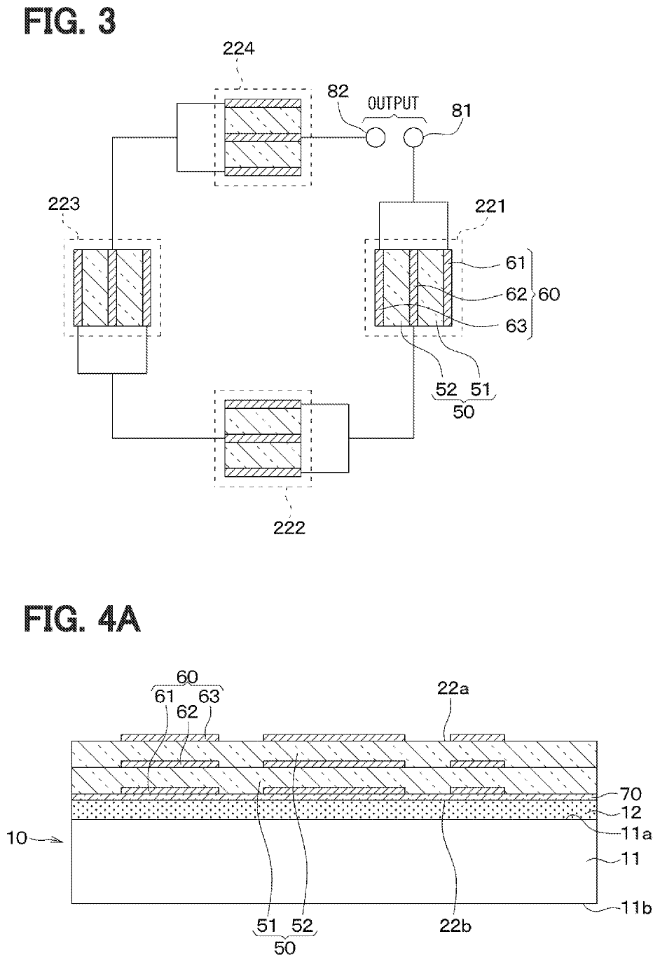

The piezoelectric element 1 of the present embodiment is configured to output a change of charges in the first to fourth vibration regions 221 to 224 as one pressure detection signal. Specifically, each of the vibration regions 221 to 224 has a bimorph structure, and as illustrated in FIG. 3, the lower electrode films 61, the intermediate electrode films 62, and the upper electrode films 63 formed in each vibration region 22 are connected in parallel, and the vibration regions 22 are connected in series. The piezoelectric element 1 outputs a potential difference between the first electrode unit 81 and the second electrode unit 82 as a pressure detection signal. In this case, for example, the second electrode unit 82 is connected to the ground, and the piezoelectric element 1 outputs a potential difference between the ground and the first electrode unit 81 as a pressure detection signal.

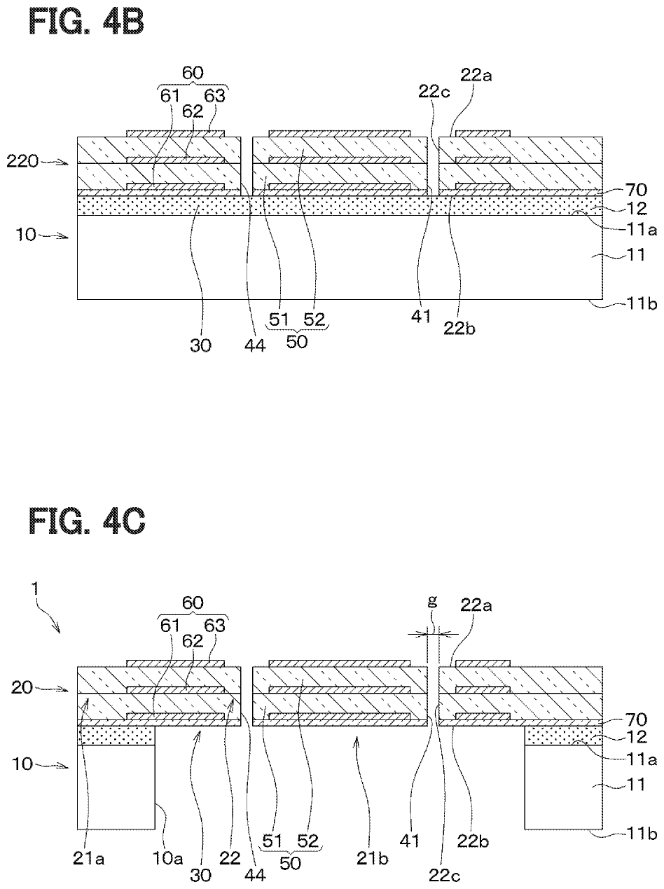

Next, a method for manufacturing such a piezoelectric element 1 will be briefly described with reference to FIGS. 4A, 4B, and 4C. FIGS. 4A to 4C are cross-sectional views of a portion corresponding to FIG. 1C.

First, as illustrated in FIG. 4A, the base film 70, the piezoelectric film 50, the electrode film 60, the first electrode unit 81, the second electrode unit 82, and the like are formed on the support 10 having the support substrate 11 and the insulating film 12. That is, a material in which the recess 10a and the first to fourth slits 41 to 44 are not formed in the piezoelectric element 1 illustrated in FIG. 1C is prepared. The piezoelectric film 50, the electrode film 60, and the like configured in the step of FIG. 4A are portions that form the vibration unit 20. Thus, in FIG. 4A, the same reference numerals as those of the one surface 22a and the other surface 22b of the vibration region 22 are given. The first electrode unit 81 and the second electrode unit 82 are formed in a different cross section from FIG. 4A.

Here, the base film 70, the piezoelectric film 50, the electrode film 60, and the like are configured by appropriately performing typical sputtering, etching, and the like. In this case, when the base film 70 and the lower electrode film 61 as the electrode film 60 are formed on the support 10, the base film 70 and the lower electrode film 61 are formed in a state where tensile stress remains because the linear expansion coefficients of the base film 70 and the lower electrode film 61 are larger than the linear expansion coefficient of the support 10. Thus, when the piezoelectric film 50 is formed as it is, the piezoelectric film 50 is likely to be formed with the tensile stress caused by the tensile stress of the base film 70 and the lower electrode film 61 remaining. When tensile stress remains in the piezoelectric film 50, characteristic fluctuation of the piezoelectric element 1 is likely to occur. Thus, the piezoelectric film 50 is preferably formed in the following manner, for example.

For example, when the upper piezoelectric film 52 is formed, it is preferable to generate compressive stress in the upper piezoelectric film 52 by increasing a voltage applied during sputtering as compared with when the lower piezoelectric film 51 is formed. This causes the tensile stress of the lower piezoelectric film 51 and the compressive stress of the upper piezoelectric film 52 to cancel each other, and the stress remaining inside the piezoelectric film 50 can be reduced as a whole. In this case, the upper piezoelectric film 52 may be formed by a plurality of times of sputtering. Then, the stress remaining inside the piezoelectric film 50 may be reduced by generating tensile stress in a portion on the lower piezoelectric film 51 side of the upper piezoelectric film 52 and generating compressive stress in a portion on the uppermost layer side, which is the opposite side from the lower piezoelectric film 51.

Next, as illustrated in FIG. 4B, anisotropic dry etching is performed using a mask (not illustrated) to form the first to fourth slits 41 to 44 that penetrate the piezoelectric film 50 and reach the support 10. As a result, a vibration region constituent part 220 to be the vibration region 22 is configured by forming the recess 10a to be described later. The second and third slits 43 and 44 are formed in a cross section different from FIG. 4B. The vibration region constituent part 220 is a portion that is configured as the vibration region 22 by forming the recess 10a. For this reason, in the drawing, one surface, the other surface, and a side surface of the vibration region constituent part 220 are denoted by the same reference numerals as the one surface 22a, the other surface 22b, and the side surface 22c of the vibration region 22.

Subsequently, as illustrated in FIG. 4C, etching is performed using a mask (not illustrated) to penetrate the insulating film 12 from the other surface 11b of the support substrate 11 and reach the base film 70, thereby forming the recess 10a. In the present embodiment, after the support substrate 11 is removed by anisotropic dry etching, the insulating film 12 is removed by isotropic wet etching to form the recess 10a. As a result, the vibration region constituent part 220 floats from the support 10 to form the vibration region 22, and the piezoelectric element 1 illustrated in FIG. 1 is manufactured.

In this step, although not illustrated, a protective resist or the like covering the upper piezoelectric film 52 and the upper electrode film 63 may be disposed to form the recess 10a. This configuration can prevent the vibration region 22 from being broken when the recess 10a is formed. The protective resist is removed after the recess 10a is formed.

The above is the configuration of the piezoelectric element 1 in the present embodiment. Next, a piezoelectric device S10 using such a piezoelectric element 1 will be described.

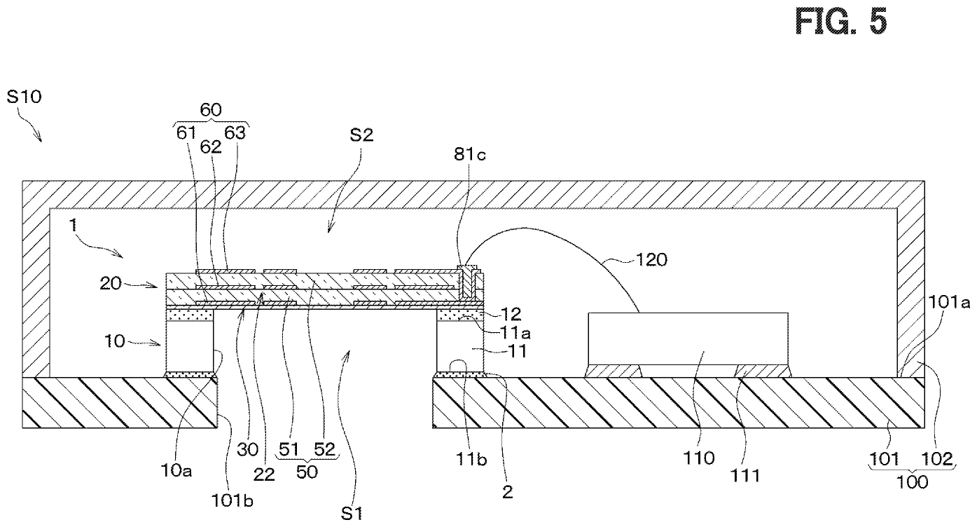

As illustrated in FIG. 5, a piezoelectric device according to the present embodiment includes the piezoelectric element 1 accommodated in a casing 100. The casing 100 includes a printed circuit board 101 on which the piezoelectric element 1 and a circuit board 110 that performs predetermined signal processing and the like are mounted, and a lid 102 fixed to the printed circuit board 101 in a manner to accommodate the piezoelectric element 1 and the circuit board 110. In the present embodiment, the printed circuit board 101 corresponds to a mounted member.

Although not illustrated, the printed circuit board 101 has a configuration in which a wiring portion, a through-hole electrode, and the like are appropriately formed, and electronic components such as a capacitor (not illustrated) are also mounted as necessary. In the piezoelectric element 1, the other surface 11b of the support substrate 11 is mounted on one surface 101a of the printed circuit board 101, with a bonding member 2, such as an adhesive, interposed between the other surface 11b and the one surface 101a. The circuit board 110 is mounted on the one surface 101a of the printed circuit board 101, with a bonding member 111 formed of a conductive member interposed between the circuit board 110 and the one surface 101a. The pad portion 81c of the piezoelectric element 1 and the circuit board 110 are electrically connected via a bonding wire 120. The pad portion 82c of the piezoelectric element 1 is electrically connected to the circuit board 110 via the bonding wire 120 in a cross section different from FIG. 5. The lid 102 is made of metal, plastic, resin, or the like, and is fixed to the printed circuit board 101 to accommodate the piezoelectric element 1 and the circuit board 110, in which a bonding member, such as an adhesive (not illustrated), is interposed between the lid 102 and the circuit board 110.

In the present embodiment, a through hole 101b communicating with the external space is formed in a portion of the printed circuit board 101 facing the sensing unit 30. Specifically, the through hole 101b has a substantially cylindrical shape, and is formed such that its central axis matches up with the center C of the vibration region 22 in the normal direction.

The above is the configuration of the piezoelectric device S10 in the present embodiment. Hereinafter, in the casing 100, a space between a portion where the through hole 101b is formed and the vibration region 22 is referred to as a pressure receiving surface space S1. A space that includes a space on the opposite side of the vibration region 22 from the pressure receiving surface space S1 and continuous with the space without the slit 40 is defined as a back space S2. The back space S2 may also be referred to as a space different from the pressure receiving surface space S1 in the space in the casing 100 and may also be referred to as a space excluding the pressure receiving surface space S1. In other words, the pressure receiving surface space S1 may also be referred to as a space that affects pressing of the surface (that is, in the present embodiment, the other surface 22b) of the vibration region 22 on the through hole 101b side formed in the casing 100. The back space S2 may also be referred to as a space that affects pressing of the surface (that is, in the present embodiment, the one surface 22a) on the opposite side from the through hole 101b formed in the casing 100 in the vibration region 22.

Next, the operation and effect of the piezoelectric device S10 will be described.

In the piezoelectric device S10 according to the present embodiment, when sound pressure as a pressure is introduced into the pressure receiving surface space S1, and the sound pressure is applied to the vibration region 22 (that is, the sensing unit 30), the vibration region 22 vibrates. In the lower piezoelectric film 51 and the upper piezoelectric film 52, charges based on the stress corresponding to a displacement of the vibration region 22 are generated. Thus, in such a piezoelectric device S10, the sound pressure is detected by extracting the charges from the first electrode unit 81 and the second electrode unit 82.

At this time, the stress generated in the vibration region 22 (that is, the piezoelectric film 50) tends to be larger on the fixed end side where the vibration region 22 is supported than on the center C side. Thus, in the piezoelectric element 1 of the present embodiment, as described above, the vibration region 22 is separated into the first region R1 where the stress tends to increase and the second region R2 where the stress tends to decrease. In the piezoelectric element 1, the lower electrode film 61, the upper electrode film 63, and the intermediate electrode film 62 disposed in the first region R1 are connected to the first and second electrode units 81 and 82, and charges generated in the lower piezoelectric film 51 and the upper piezoelectric film 52 positioned in the first region R1 are extracted. As a result, the influence of noise can be prevented from increasing.

Here, the resonance frequency f of the vibration region 22 in the piezoelectric element 1 (hereinafter, also simply referred to as a resonance frequency f of the piezoelectric element 1) depends on the spring constant k of the vibration region 22 serving as a beam and the mass m of the vibration region 22, and is expressed by the following Mathematical Formula 1.

$$f = \frac{1}{2} \times π \times {( \frac{k}{m} )}^{\frac{1}{2}} \qquad ( Mathematical Formula 1 )$$

In this case, it is difficult to reduce the mass m because the piezoelectric film 50 is a thin film of about 1 μm in the piezoelectric element 1 as described above. Thus, in the present embodiment, the vibration region 22 has a double-supported structure to increase the spring constant k. As a result, the resonance frequency f can be increased.

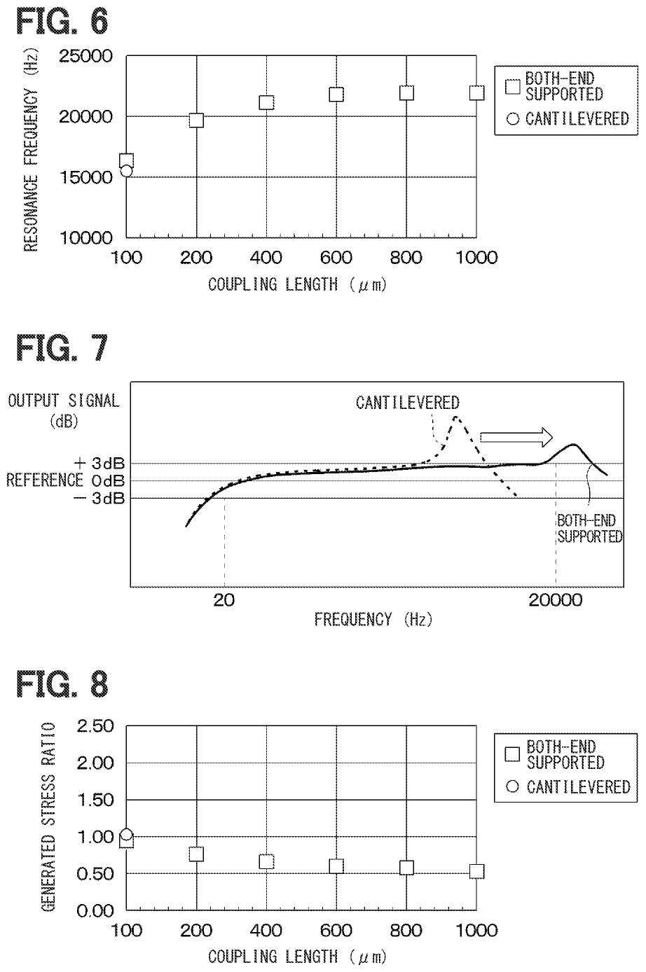

For example, as illustrated in FIG. 2A, a length between the first slit 41 and the center C of the vibration region 22 is defined as a first length X, and a length between the second slit 42 and the center C of the vibration region 22 is defined as a second length Y. In the present embodiment, since the slit lengths L of the first to fourth slits 41 to 44 are equal as described above, the first length X and the second length Y are equal. Assuming that the sum of the first length X and the second length Y is a coupling length (that is, X+Y), the relationship between the coupling length and the resonance frequency f is shown as in FIG. 6.

Specifically, in a case where the vibration region 22 is supported at both ends, the spring constant (that is, rigidity) increases as the coupling length increases. Thus, it is confirmed that the resonance frequency f increases as compared with a case where the vibration region 22 is cantilevered. Thus, as shown in FIG. 7, the resonance frequency f can be made larger than 20,000 Hz (that is, 20 kHz), which is an audible range, by adjusting the coupling length. In other words, when the output signal with the frequency of 1,000 Hz (that is, 1 kHz) is a reference (that is, 0 dB), the resonance frequency f can be made to exist at a frequency higher than the frequency at which the output signal is +3 dB by adjusting the coupling length. As a result, the frequency at which the detection sensitivity can be maintained can be widened. However, in the vibration region 22 of the present embodiment, since the thickness of the piezoelectric film 50 is about 1 μm, the resonance frequency f is saturated at about 22.5 kHz when the coupling length is about 300 μm. The frequency at which the detection sensitivity can be maintained can be further widened by allowing the low-frequency roll-off frequency to exist at a frequency at which the output signal is smaller than −3 dB. The low-frequency roll-off frequency will be specifically described in the eighth embodiment described later.

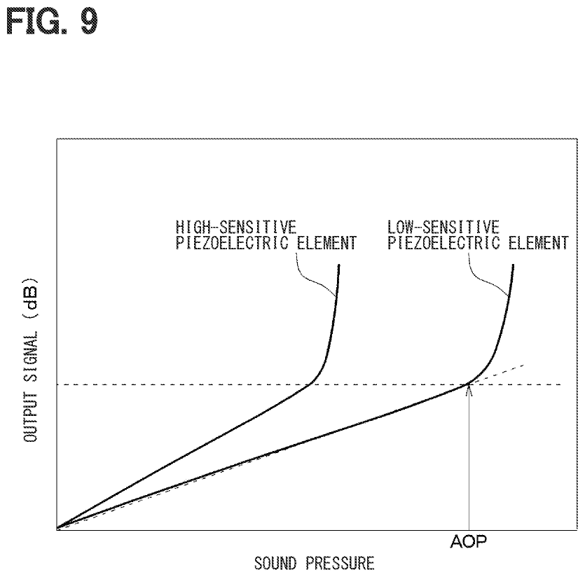

As shown in FIG. 8, as the coupling length increases, the spring constant increases and the vibration region 22 is less likely to be deformed, and thus the generated stress ratio decreases. That is, the sensitivity lowers as the coupling length becomes longer. In this case, as shown in FIG. 9, assuming that the frequency of the sound pressure to be input is constant, it is possible to increase the acoustic over point (AOP) by lowering the sensitivity. Thus, the coupling length is preferably adjusted depending on the use application. The generated stress ratio in FIG. 8 is based on the stress generated at the boundary between the vibration region 22 and the support region 21a when the vibration region 22 is cantilevered. The generated stress ratio indicates the ratio of the stress generated at the boundary between the vibration region 22 and the support region 21a when the vibration region 22 is supported at both ends to the reference stress.

According to the present embodiment described above, in the piezoelectric element 1, the vibration region 22 is supported at both ends. Thus, the resonance frequency f can be increased as compared with the case where the vibration region 22 is cantilevered. Thus, the frequency at which the detection sensitivity can be maintained can be widened, and the detection accuracy can be improved.
(1) In the present embodiment, the resonance frequency f of the piezoelectric element 1 may be 20 kHz or more. Thus, in such a piezoelectric element 1, the resonance frequency f can be set outside the audible range, and the frequency at which the detection sensitivity in the audible range can be maintained can be widened.

### Modification of First Embodiment

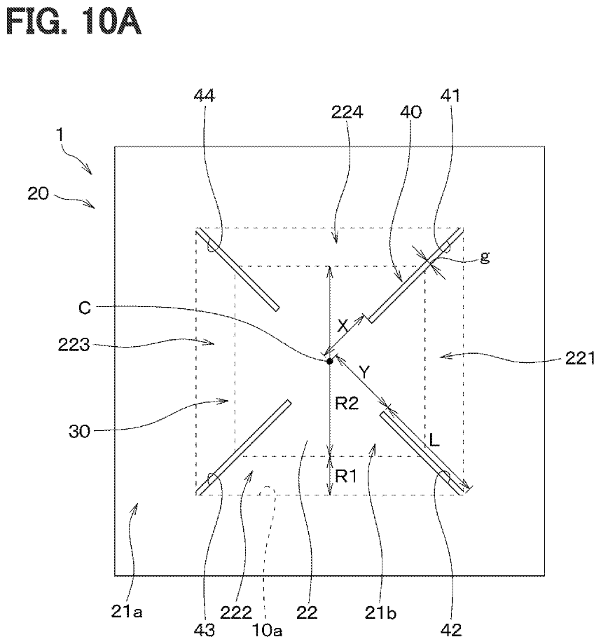

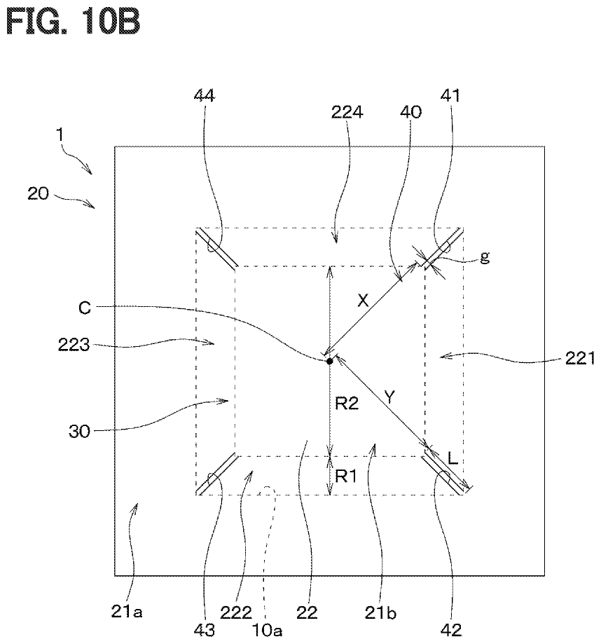

A modification of the first embodiment will be described. As described above, it is preferable that the coupling length is appropriately adjusted according to the use application and the relationship with the detection sensitivity. In this case, as illustrated in FIG. 10A, the slit lengths L of the first slit 41 and the third slit 43 may be different from the slit lengths L of the second slit 42 and the fourth slit 44. The first length X and the second length Y do not have to have the same distance, and the first length X may be shorter than the second length Y. Although not illustrated, the first length X may be longer than the second length Y.

Further, as illustrated in FIG. 10B, the first to fourth slits 41 to 44 may be formed only in the first region R1 in the vibration region 22. Although not illustrated, the slit lengths L of the first to fourth slits 41 to 44 may be different from each other.

In this manner, in the piezoelectric element 1 of the present embodiment, the slit lengths L of the first to fourth slits 41 to 44 can be appropriately changed. They can be changed according to a product to be mounted. Thus, in the piezoelectric element 1 of the present embodiment, the selectivity of the product to be mounted can also be improved.

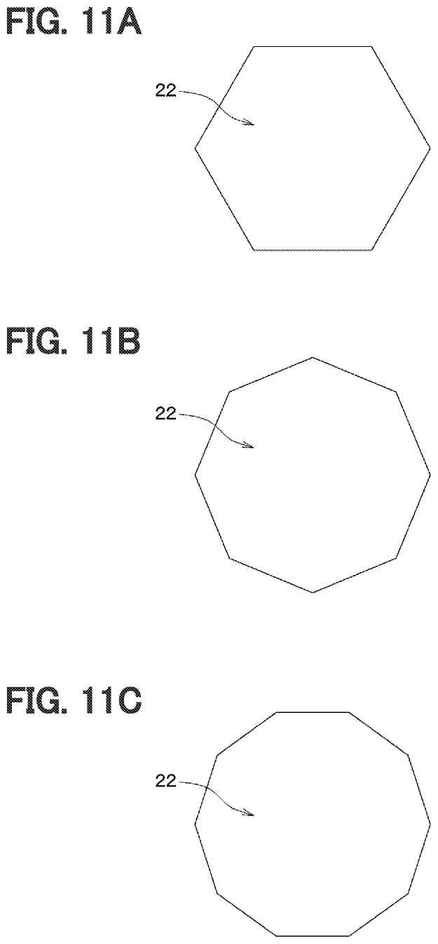

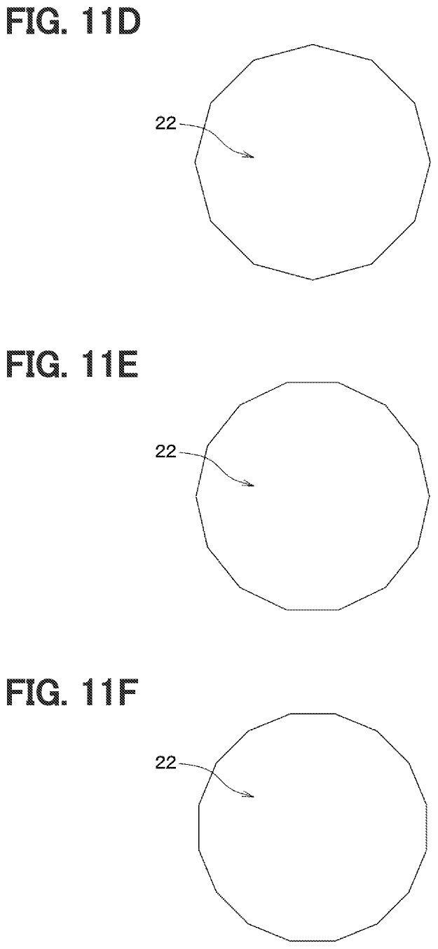

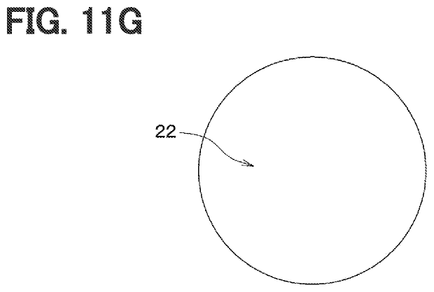

The planar shape of the vibration region 22 may be changed as appropriate. For example, as illustrated in FIGS. 11A to 11G, the vibration region 22 may have a planar shape of a hexagonal shape, an octagonal shape, a decagonal shape, a dodecagonal shape, a tetradecagonal shape, a hexadecagonal shape, or a circular shape. Although not illustrated, the vibration region 22 may have another polygonal shape. In FIGS. 11A to 11G, the slit 40 formed in the vibration region 22 is omitted, but the slit 40 is formed in each vibration region 22. For example, when the planar shape of the vibration region 22 is a hexagonal shape as illustrated in FIG. 11A, six slits 40 are formed from the corners of the outer shape of the vibration region 22 toward the center C. When the planar shape of the vibration region 22 is a circular shape as illustrated in FIG. 11G, a plurality of desired slits 40 are formed uniformly in a circumferential direction.

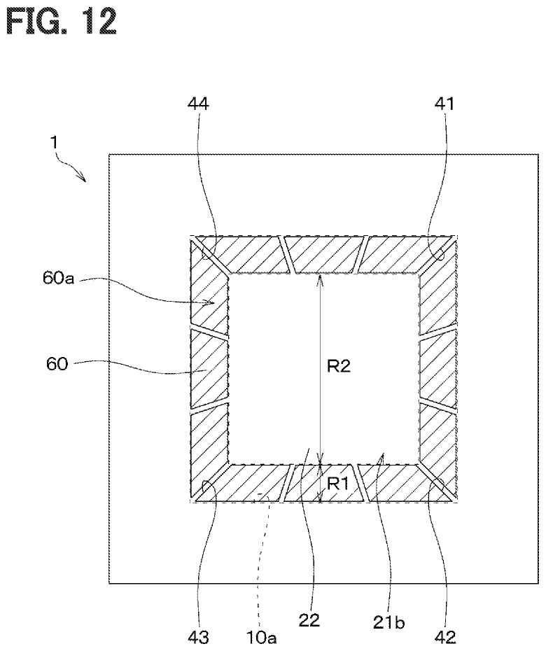

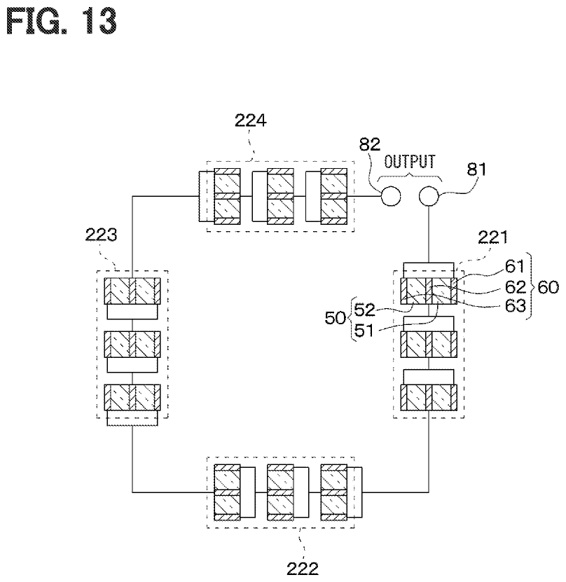

Further, as illustrated in FIG. 12, the electrode film 60 may be divided into a plurality of charge regions 60a in the first region R1. For example, the electrode film 60 may be divided into three charge regions 60a in the first region R1 of each of the vibration regions 221 to 224. The lower electrode film 61, the intermediate electrode film 62, and the upper electrode film 63 to be the electrode film 60 are each divided into charge regions 60a in the first region R1 as illustrated in FIG. 12. In this case, as illustrated in FIG. 13, the piezoelectric element 1 is in a state where the capacitances configured by the divided charge regions 60a are connected in series. According to this, the capacitance in each of the vibration regions 221 to 224 can be reduced, and the output can be improved. That is, the detection sensitivity can be improved.

### Second Embodiment

A second embodiment will be described. The present embodiment is different from the first embodiment in the shapes of the first to fourth slits 41 to 44. The other configurations are the same as those of the first embodiment, and thus the description thereof is omitted here.

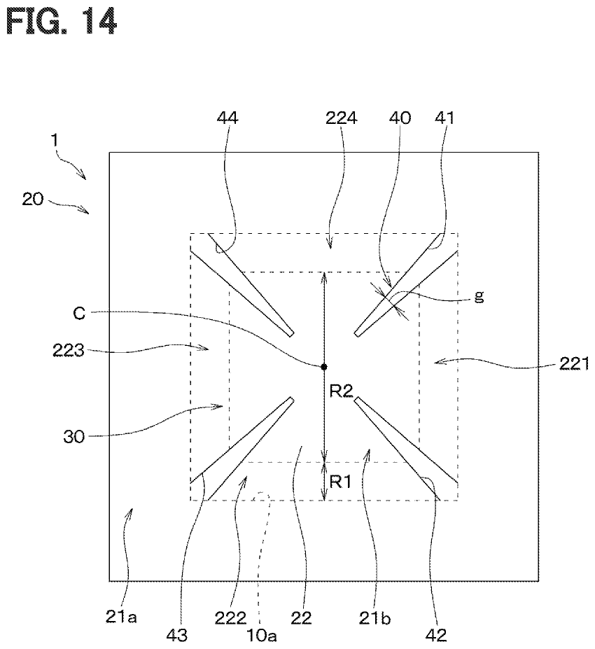

In the piezoelectric element 1 of the present embodiment, as illustrated in FIG. 14, the first to fourth slits 41 to 44 have a tapered shape in which the slit width g decreases toward the center C in a normal direction.

According to the present embodiment described above, the vibration region 22 is supported at both ends. Thus, the resonance frequency f of the piezoelectric element 1 can be increased, and the same effect as in the first embodiment can be obtained.
(1) In the present embodiment, the first to fourth slits 41 to 44 have a tapered shape in which the slit width g decreases toward the center C of the vibration region 22. Thus, when sound pressure is applied to the vibration region 22 and the vibration region 22 bends, the slit width g of the first to fourth slits 41 to 44 can be easily equalized with the vibration region bending. In other words, when the vibration region 22 bends, the slit width g of the first to fourth slits 41 to 44 can be easily equalized between a portion on the support region 21a side and a portion on the center C side in the normal direction. Thus, a difference hardly occurs in ease of local sound pressure release in the first to fourth slits 41 to 44, and noise can be reduced. Thus, the detection accuracy can be further improved.

### Third Embodiment

A third embodiment will be described. The present embodiment is different from the first embodiment in the manner of partitioning the first region R1 and the second region R2. The other configurations are the same as those of the first embodiment, and thus the description thereof is omitted here.

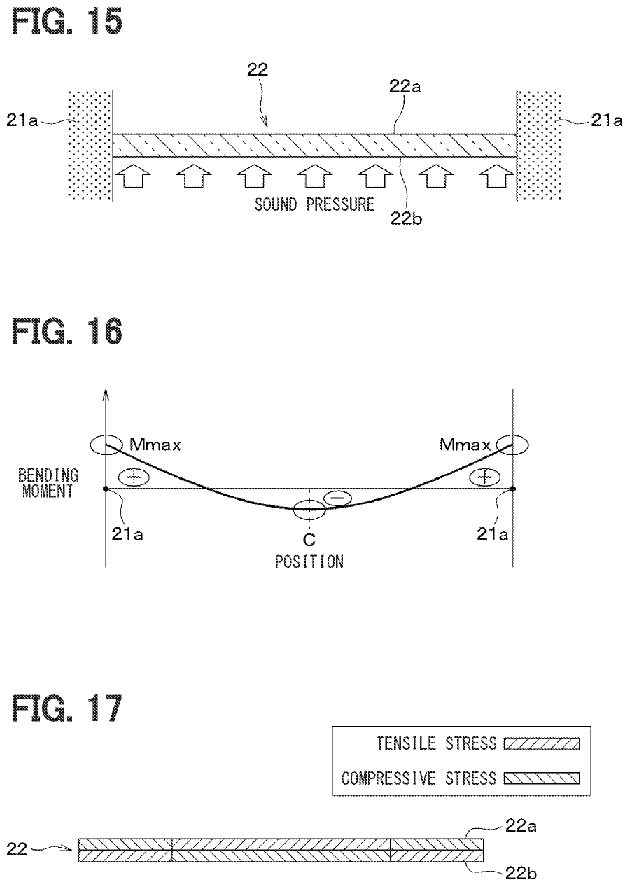

The piezoelectric element 1 of the present embodiment has the same configuration as that of the first embodiment, and the vibration region 22 is supported at both ends. Here, as illustrated in FIG. 15, it is assumed that sound pressure is applied from the other surface 22b side of the vibration region 22. In this case, as illustrated in FIG. 16, in the vibration region 22, a maximum bending moment Mmax is generated on the support region 21a side, and a large bending moment is also generated in the center C. In the piezoelectric film 50, opposite stresses are generated in the lower piezoelectric film 51 and the upper piezoelectric film 52 as illustrated in FIG. 17. In the piezoelectric film 50, opposite stresses are generated at the outer edge portion on the support region 21a side and the inner edge portion on the center C side. That is, in the piezoelectric film 50, opposite stresses are generated in a portion in the first region R1 and a portion on the center C side.

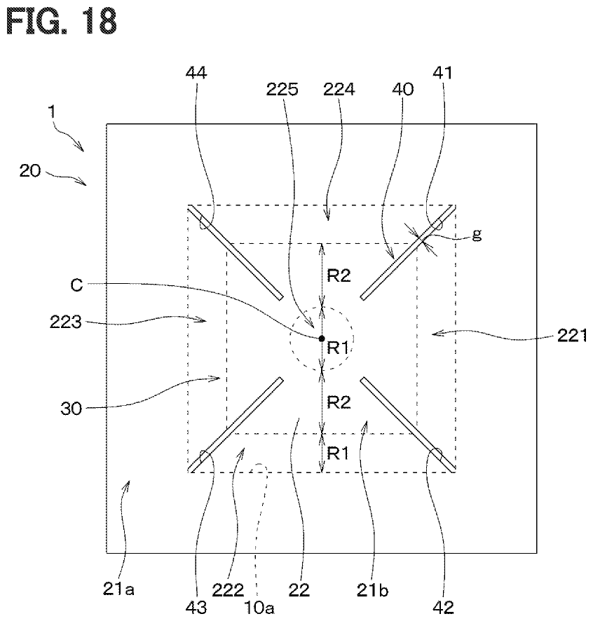

Thus, in the present embodiment, as illustrated in FIG. 18, a center region 225 including the center C of the vibration region 22 and its peripheral portion is also set as the first region R1, and the charges of the center region 225 is also extracted. The center region 225 may also be referred to as a region constituted by a region on the center C side in the first to fourth vibration regions 221 to 224.

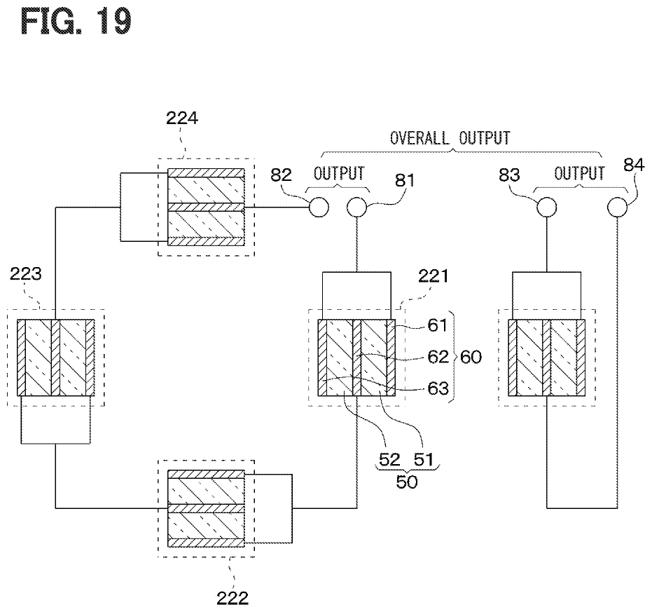

Specifically, in the present embodiment, as illustrated in FIG. 19, the charges of the center region 225 are combined and output with the charges in the first to fourth vibration regions 221 to 224. Specifically, in the piezoelectric element 1 of the present embodiment, a third electrode unit 83 and a fourth electrode unit 84 are formed in addition to the first electrode unit 81 and the second electrode unit 82. In the center region 225, the lower electrode film 61 and the upper electrode film 63 are electrically connected to the third electrode unit 83, and the intermediate electrode film 62 is connected to the fourth electrode unit 84. The fourth electrode unit 84 connected to the intermediate electrode film 62 is connected to the ground, for example, similarly to the second electrode unit 82. In the piezoelectric film 50, opposite stresses are generated in a portion in the first region R1 and a portion in the center region 225. Thus, the piezoelectric element 1 outputs a difference between the output based on the potential difference between the first electrode unit 81 and the second electrode unit 82 and the output based on the potential difference between the third electrode unit 83 and the fourth electrode unit 84 as the entire pressure detection signal.

According to the present embodiment described above, the vibration region 22 is supported at both ends. Thus, the resonance frequency f of the piezoelectric element 1 can be increased, and the same effect as in the first embodiment can be obtained.
(1) In the present embodiment, the charges of the center region 225 in the vibration region 22 is also extracted. Thus, the detection sensitivity can be improved.

### Fourth Embodiment

A fourth embodiment will be described. The present embodiment is different from the first embodiment in the configuration of the vibration region 22. The other configurations are the same as those of the first embodiment, and thus the description thereof is omitted here.

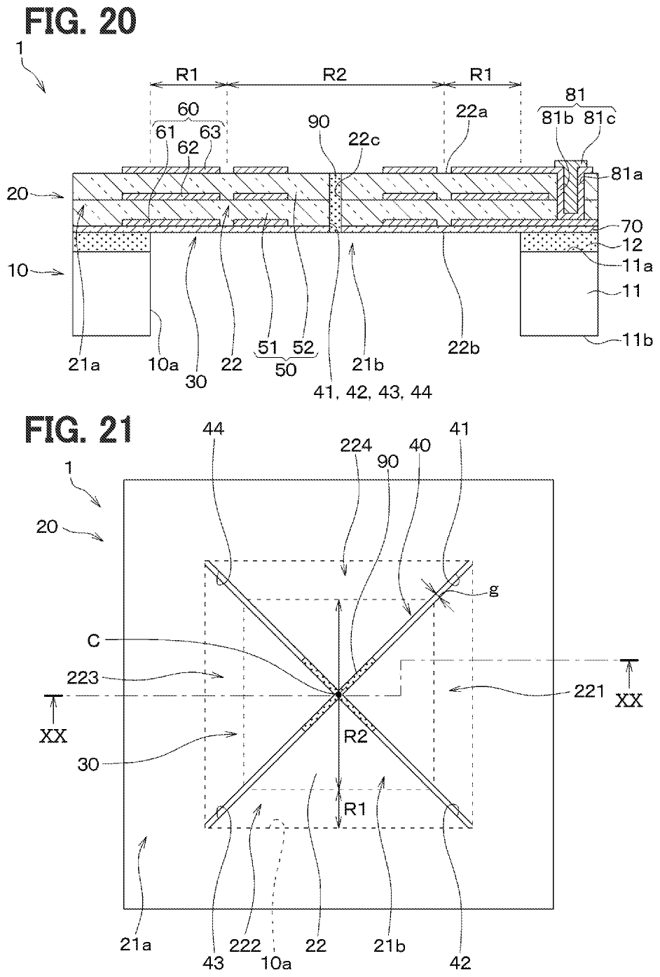

In the piezoelectric element 1 of the present embodiment, as illustrated in FIGS. 20 and 21, the first to fourth slits 41 to 44 is extended to the center C of the vibration region 22. That is, the first to fourth slits 41 to 44 are formed to intersect at the center C. Thus, the first to fourth vibration regions 221 to 224 are partitioned by the first to fourth slits 41 to 44. FIG. 20 corresponds to a cross-sectional view taken along line XX-XX in FIG. 21. FIG. 21 is not a cross-sectional view, but a coupling member 90 to be described later for is hatched for easy understanding.

In the present embodiment, the coupling member 90 is embedded in the center C and the vicinity of the center C in the first to fourth slits 41 to 44. In the present embodiment, the first to fourth vibration regions 221 to 224 are integrated by the coupling member 90, and the vibration regions 22 is supported at both ends by the support region 21a. The coupling member 90 of the present embodiment is made of a material having lower rigidity than the piezoelectric film 50. For example, the coupling member 90 is made of a material obtained by mixing a polyimide component with an ionic liquid and curing the mixture by a heat treatment at about 150° C. The ionic liquid is a liquid compound of a salt composed of only ions (that is, anions and cations).

Such a piezoelectric element 1 is manufactured as follows, for example. That is, the first to fourth slits 41 to 44 are made to intersect at the center C of the vibration region 22 when the first to fourth slits 41 to 44 are formed in the step of FIG. 4B. Thereafter, a photoresist or the like is disposed to cover the upper electrode film 63 or the like, and the photoresist is patterned to form an opening in a portion where the coupling member 90 is to be disposed. Next, the coupling member 90 is embedded in the first to fourth slits 41 to 44 by a spin coating method or the like and cured by a heat treatment. Subsequently, lifting off is performed to remove the photoresist to form a state where the coupling member 90 is disposed in the first to fourth slits 41 to 44. Thereafter, the step of FIG. 4C is performed, whereby the piezoelectric element 1 illustrated in FIGS. 20 and 21 is manufactured.

According to the present embodiment described above, the vibration region 22 is supported at both ends. Thus, the resonance frequency f of the piezoelectric element 1 can be increased, and the same effect as in the first embodiment can be obtained.
(1) As in the present embodiment, the vibration region 22 may be supported at both ends by the coupling member 90.
(2) In the present embodiment, the coupling member 90 is made of a material having lower rigidity than the piezoelectric film 50. Thus, the influence of the coupling member 90 on the detection sensitivity of the piezoelectric element 1 can be reduced.

### Fifth Embodiment

A fifth embodiment will be described. The present embodiment is different from the fourth embodiment in the configuration of the vibration region 22. The other configurations are the same as those of the fourth embodiment, and thus the description thereof is omitted here.

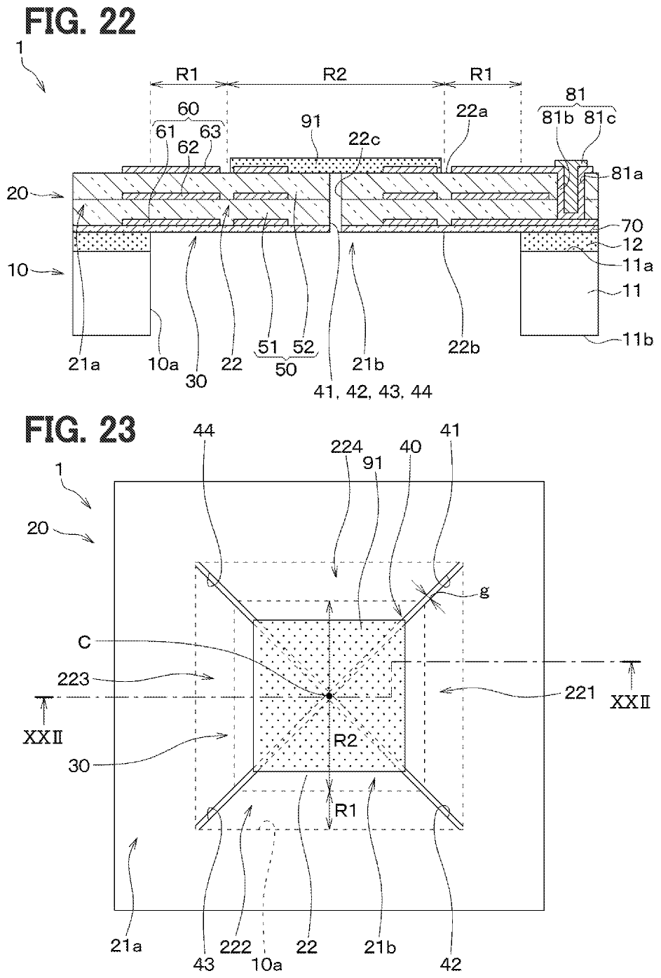

In the piezoelectric element 1 of the present embodiment, as illustrated in FIGS. 22 and 23, the coupling member 90 is not disposed in the first to fourth slits 41 to 44, and a coupling member 91 is disposed on the one surface 22a of the vibration region 22. FIG. 22 corresponds to a cross-sectional view taken along line XXII-XXII in FIG. 23. FIG. 23 is not a cross-sectional view, but the coupling member 91 to be described later is hatched for easy understanding.

Specifically, the coupling member 91 is disposed on the one surface 22a of the vibration region 22 to cover (that is, to straddle) the center C and a portion in the vicinity of the center C in the first to fourth slits 41 to 44. In the present embodiment, the first to fourth vibration regions 221 to 224 are integrated in this manner, and the vibration region 22 is in a state of being supported at both ends by the support region 21a. The coupling member 91 is made of a material having lower rigidity than the piezoelectric film 50. For example, the coupling member 91 is made of polyimide or the like. More specifically, the coupling member 91 is made of polydimethylsiloxane (that is, PDMS) or the like.

Such a piezoelectric element 1 is manufactured as follows, for example. That is, after the first to fourth slits 41 to 44 are formed to intersect at the center C of the vibration region 22, the coupling member 91 is disposed by a spin coating method or the like. In the present embodiment, the viscosity of the coupling member 91 is adjusted so that the coupling member 91 does not enter the first to fourth slits 41 to 44 when the spin coating method is performed. Subsequently, the coupling member 91 is patterned using a photoresist. Thereafter, the step of FIG. 4C is performed, whereby the piezoelectric element 1 illustrated in FIGS. 22 and 23 is manufactured.

According to the present embodiment described above, the vibration region 22 is supported at both ends. Thus, the resonance frequency f of the piezoelectric element 1 can be increased, and the same effect as in the first embodiment can be obtained.
(1) As in the present embodiment, the vibration region 22 may be supported at both ends by the coupling member 91.
(2) In the present embodiment, since the coupling member 91 is made of a material having lower rigidity than the piezoelectric film 50, the same effect as in the fourth embodiment can be obtained.

### Sixth Embodiment

In the present embodiment, the shapes of the vibration region 22 and the intermediate electrode film 62 is adjusted with respect to the first embodiment. The other configurations are the same as those of the first embodiment, and thus the description thereof is omitted here.

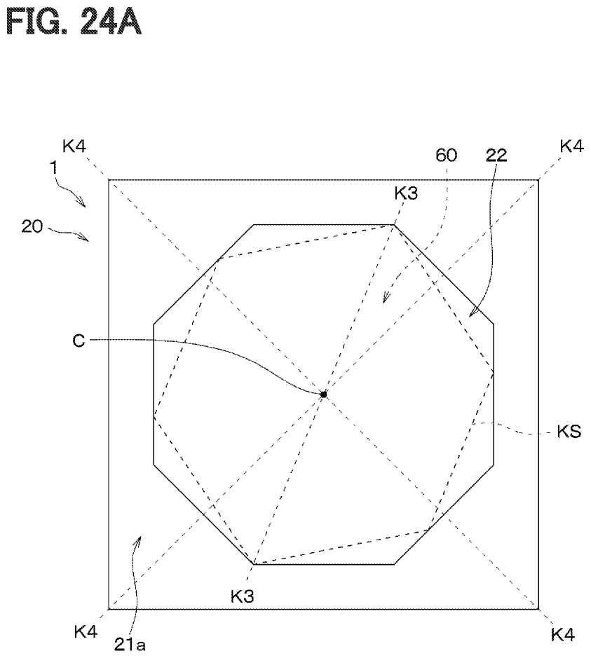

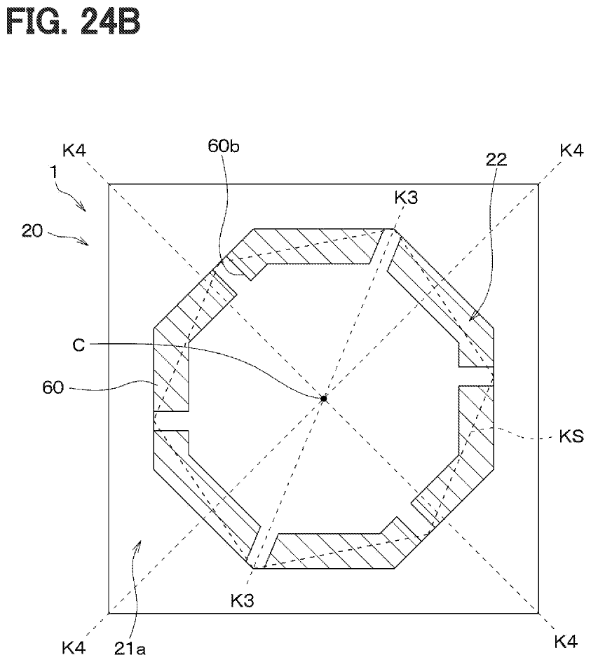

The piezoelectric element 1 of the present embodiment will be described with reference to FIGS. 24A and 24B. In FIG. 22, the slit 40 is omitted. However, the slit 40 is extended from each corner in a planar shape of the vibration region 22 toward the center C as in the first embodiment in practice.

As illustrated in FIG. 24A, the vibration region 22 has a regular octagonal outer shape in the normal direction. That is, the recess 10a of the support 10 has a regular octagonal opening. Hereinafter, the reason the vibration region 22 has a regular octagonal shape will be described. As described above, in the present embodiment, the support substrate 11 is made of silicon. Thus, distortions can be prevented from concentrating in a local portion of the opening end of the recess 10a in the support substrate 11 (that is, the outer end portion of the vibration region 22) by forming the opening of the recess 10a (that is, the outer shape of the vibration region 22) into a regular octagonal shape. Thus, distortions can be prevented from concentrating in a local portion of the boundary between the vibration region 22 and the support region 21a.

In the electrode film 60 of the present embodiment, the outer shape of the portion formed in the first region R1 in the normal direction is a regular octagonal shape as illustrated in FIG. 24B. That is, the electrode film 60 is formed such that the outer edge portion substantially matches up with the opening end of the recess 10a in the first region. In the electrode film 60, the portion formed in the first region R1 is separated by an electrode film slit 60b different from the slit 40. Specifically, six electrode film slits 60b are formed such that a virtual shape KS formed by connecting predetermined portions in the electrode film slits 60b (hereinafter, also simply referred to as a virtual shape) has a hexagonal shape. More specifically, the electrode film slit 60b is formed such that the virtual shape KS formed by connecting the portions where the electrode film slits 60b intersect with the outer shape of the electrode film 60 has a hexagonal shape.

The outer shape of the portion of the electrode film 60 positioned in the first region R1 is, as described above, a shape formed by the outline of the portion of the electrode film 60 positioned in the first region R1 and an extension line of the outline.

Hereinafter, the reason the virtual shape KS of the electrode film 60 has a hexagonal shape will be described. As described above, the electrode film 60 and the piezoelectric film 50 are disposed by stacking the lower electrode film 61, the lower piezoelectric film 51, the intermediate electrode film 62, the upper piezoelectric film 52, and the upper electrode film 63 in this order. When the lower electrode film 61, the intermediate electrode film 62, and the upper electrode film 63 are formed, a metal film is formed, and then the metal film is patterned into a desired shape by dry etching or the like using a mask. At this time, although a mask is used, there is a possibility that the lower piezoelectric film 51 or the upper piezoelectric film 52 serving as a base is etched. In this case, the piezoelectric film 50 has a hexagonal crystal structure when it is made of ScAlN, AlN, or the like, and thus, it is possible to prevent the crystallinity of the piezoelectric film 50 from collapsing when the surface of the piezoelectric film 50 is etched, by forming the virtual shape KS of the electrode film 60 into a hexagonal shape. That is, the characteristic of the piezoelectric film 50 can be prevented from varying by matching the portion where the electrode film slit 60b is formed with the crystal configuration of the piezoelectric film 50.

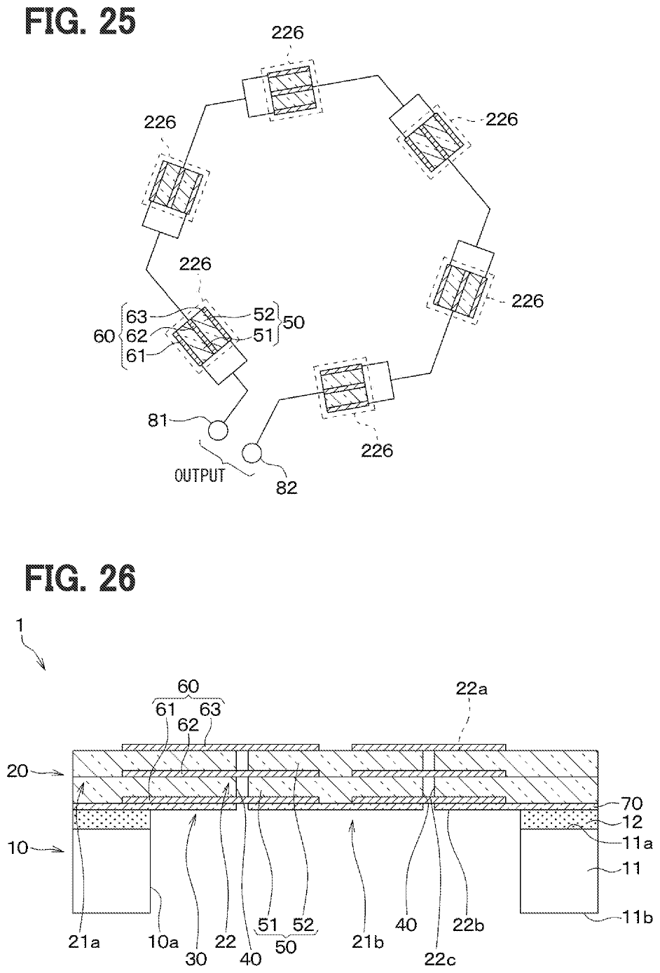

In the piezoelectric element 1 of the present embodiment, capacitances between the electrode films 61 to 63 are connected as illustrated in FIG. 25. In the present embodiment, as described above, the electrode film 60 is divided into six pieces by the electrode film slits 60b different from the slit 40. Thus, the piezoelectric element 1 of the present embodiment has six divided regions 226 and outputs a pressure detection signal based on the capacitance of each region 226.

The electrode film 60 of the present embodiment is separated by the electrode film slits 60b as described above but is not separated by the slit 40. Thus, as illustrated in FIG. 26, the electrode film 60 is in a connected state at the portion where the slit 40 is formed. Such a piezoelectric element 1 is manufactured, for example, by forming the slit 40 or the electrode film slit 60b every time each film is formed when the steps of FIGS. 4A and 4B are performed. For example, after the base film 70 is formed, a metal film is formed on the base film 70. Then, the electrode film slit 60b is formed when the metal film is patterned to form the lower electrode film 61. Thereafter, the lower piezoelectric film 51 is formed on the lower electrode film 61, and the slit 40 penetrating only the lower piezoelectric film 51 may be formed in the lower piezoelectric film 51 before the intermediate electrode film 62 is formed. Thereafter, the intermediate electrode film 62, the upper piezoelectric film 52, and the upper electrode film 63 are also formed in the same manner, whereby the piezoelectric element 1 of the present embodiment is manufactured.

In the electrode film 60 of the present embodiment, in practice, the outer edge end portion opposite from the center C is formed up to the outside of the first region R1, and the inner edge end portion is formed up to the inside of the second region R2. Thus, when a metal film is formed then the intermediate electrode film 62 and the upper electrode film 63 are formed by patterning the metal film into a desired shape, the piezoelectric film 50 outside the first region R1 is removed when the piezoelectric film 50 is removed in a portion different from the electrode film slit 60b. Thus, deterioration in the detection accuracy can be prevented by forming the virtual shape KS into a hexagonal shape.

The vibration region 22 and the virtual shape KS of the electrode film 60 are disposed to be symmetric with respect to the center C. In the present embodiment, in the normal direction, the virtual shape KS of the electrode film 60 is a hexagonal shape, and the outer shape of the vibration region 22 is a regular octagonal shape. The vibration region 22 and the electrode film 60 are disposed such that two opposite vertices of the virtual shape KS of the electrode film 60 match up with two opposite vertices of the outer shape of the vibration region 22. In other words, two opposite vertices of the virtual shape KS of the electrode film 60 are disposed on a virtual line K3 connecting two opposite vertices in the vibration region 22.

Further, the piezoelectric element 1 (that is, the vibration unit 20) of the present embodiment has a rectangular shape in a plane as described above. The vibration region 22 and the virtual shape KS of the electrode film 60 are formed such that each corner is positioned at a portion different from a portion on a virtual line K4 connecting opposite corners of the outer shape of the piezoelectric element 1.

According to the present embodiment described above, the vibration region 22 is supported at both ends. Thus, the resonance frequency f of the piezoelectric element 1 can be increased, and the same effect as in the first embodiment can be obtained.
(1) In the present embodiment, the vibration region 22 and the electrode film 60 are disposed to be symmetric with respect to the center C in the normal direction. Thus, when sound pressure is applied to the vibration region 22, charges can be easily extracted uniformly from the electrode film 60. Thus, deterioration in the detection sensitivity can be prevented, and deterioration in the detection accuracy can be prevented.
(2) In the present embodiment, the vibration region 22 and the virtual shape KS of the electrode film 60 are formed such that each corner is positioned at a portion different from a portion on the virtual line K4 connecting opposite corners of the outer shape of the piezoelectric element 1. Thus, deterioration in the detection accuracy can be prevented. That is, in the piezoelectric element 1, a portion on the virtual line K4 connecting opposite corners is easily distorted by thermal stress or the like. In this case, when a corner of the vibration region 22 or a corner of the virtual shape KS of the electrode film 60 is positioned on the virtual line K4, a large thermal stress is likely to be applied to the corner that is easily deformed, and noise tends to increase. Thus, each corner of the vibration region 22 and each corner of the electrode film 60 are positioned at a portion different from the portion on the virtual line K4 as in the present embodiment, and thus deterioration in the detection accuracy can be prevented.
(3) In the present embodiment, the virtual shape KS of the electrode film 60 is a hexagonal shape. Thus, the crystallinity of the piezoelectric film 50 can be prevented from collapsing when the electrode film 60 is formed by patterning. Thus, the characteristics of the piezoelectric element 1 can be prevented from varying.
(4) In the present embodiment, the outer shape of the vibration region 22 is a regular octagonal shape. Thus, distortions can be prevented from concentrating in a local portion of the vibration region 22.

### Modification of Sixth Embodiment

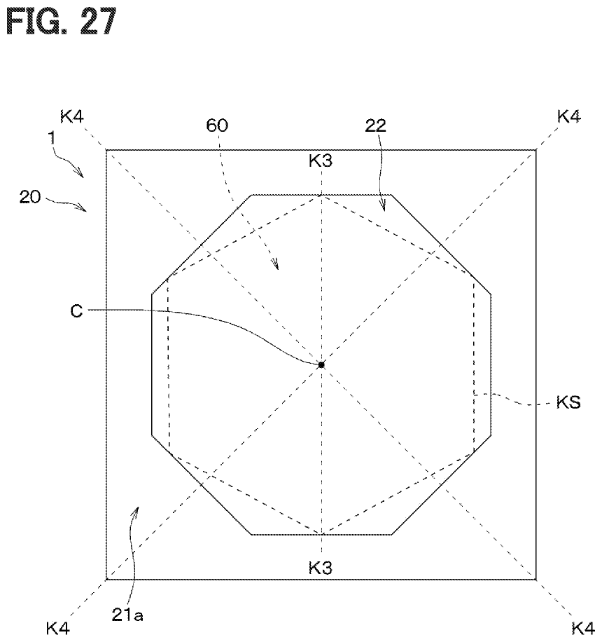

A modification of the sixth embodiment will be described. In the sixth embodiment, charges can be easily extracted uniformly from the electrode film 60 as in the sixth embodiment when the vibration region 22 and the electrode film 60 are disposed to be symmetric with respect to the center C. Thus, for example, as illustrated in FIG. 27, the vibration region 22 and the electrode film 60 may be disposed such that a pair of vertices of the virtual shape KS in the electrode film 60 are positioned on the virtual line K3 connecting the centers of a pair of sides opposing each other in the vibration region 22 and the center C. Even in such a configuration, it is preferable that the vibration region 22 and the electrode film 60 are formed such that each corner is positioned at a portion different from the portion on the virtual line K4. In FIG. 27, illustration of the slit 40 is omitted as in FIG. 24A.

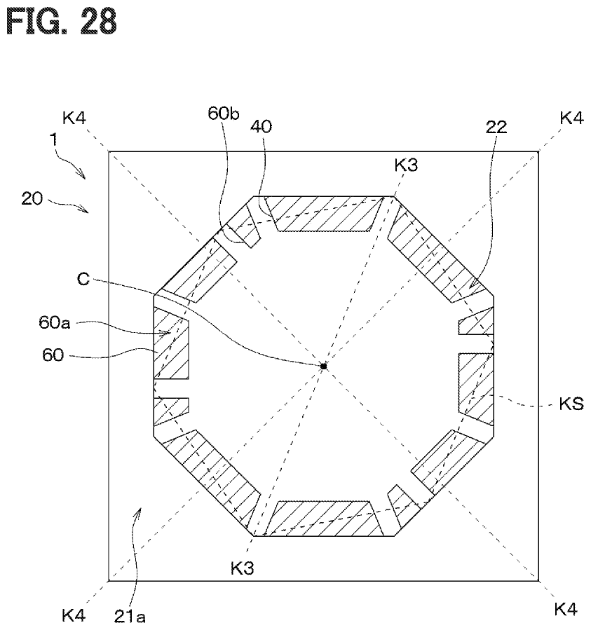

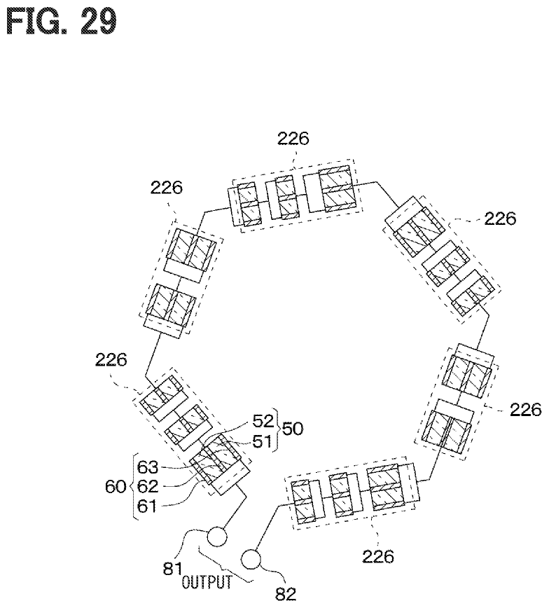

Further, in the sixth embodiment, as in the modification of the first embodiment, the electrode film 60 may be divided into a plurality of charge regions 60a in the first region R1 as illustrated in FIG. 28. Then, the divided charge regions 60a may be connected in series as illustrated in FIG. 29. When the electrode film 60 is configured as described above, the electrode film 60 may be formed by the slit 40 formed in the piezoelectric film 50.

### Seventh Embodiment

A seventh embodiment will be described. In the present embodiment, a formation place of the through hole 101b of the piezoelectric device S10 is specified with respect to the first embodiment. The other configurations are the same as those of the first embodiment, and thus the description thereof is omitted here.

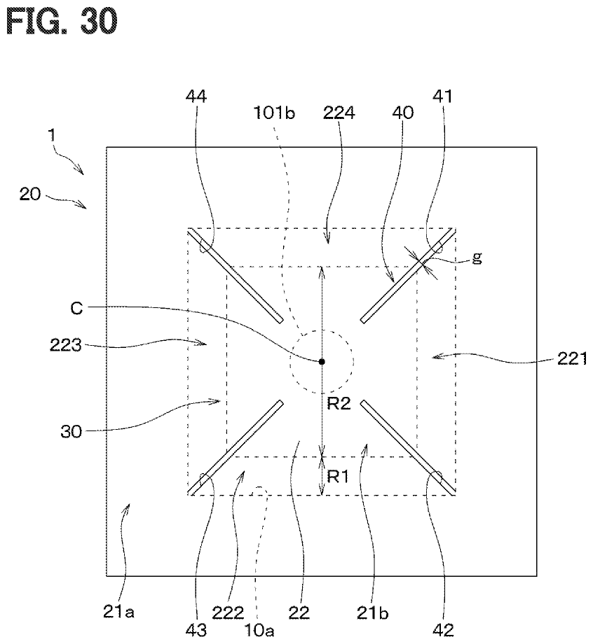

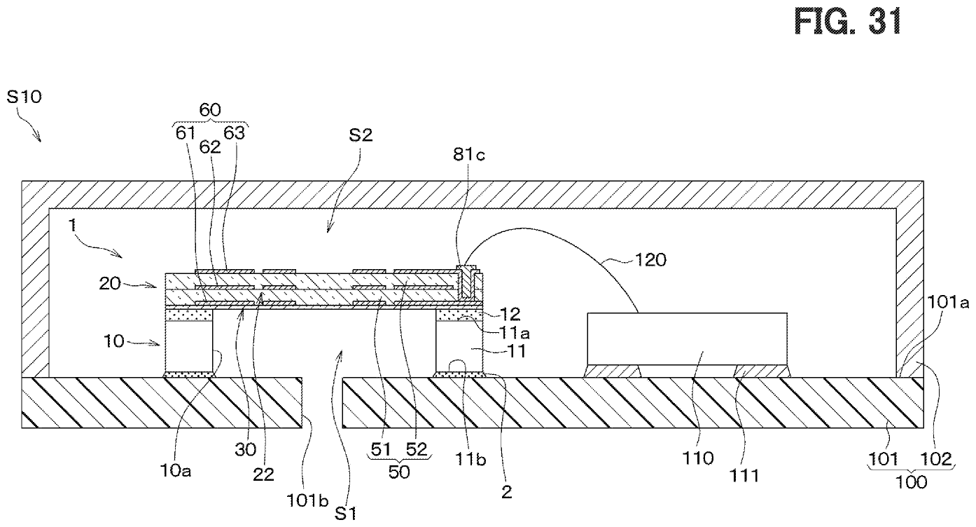

In the piezoelectric device S10 of the present embodiment, as illustrated in FIGS. 30 and 31, the first to fourth slits 41 to 44 are formed in portions different from a portion facing the through hole 101b formed in the printed circuit board 101. In other words, the through hole 101b is formed in a portion of the printed circuit board 101 different from a portion facing the first to fourth slits 41 to 44. In FIG. 30, the portion facing the through hole 101b is indicated by broken lines.

According to the present embodiment described above, the vibration region 22 is supported at both ends. Thus, the resonance frequency f of the piezoelectric element 1 can be increased, and the same effect as in the first embodiment can be obtained.
(1) In the present embodiment, the first to fourth slits 41 to 44 are formed in portions different from a portion facing the through hole 101b formed in the printed circuit board 101. Thus, sound pressure can be prevented from directly flowing into the back space S2 through the first to fourth slits 41 to 44. As a result, the noise caused by Brownian motion of the first to fourth slits 41 to 44 can be reduced. In addition, foreign matters such as dust can be prevented from accumulating in the first to fourth slits 41 to 44.

### Eighth Embodiment

An eighth embodiment will be described. In the present embodiment, the slit length L and the like are defined with respect to the first embodiment. The other configurations are the same as those of the first embodiment, and thus the description thereof is omitted here.

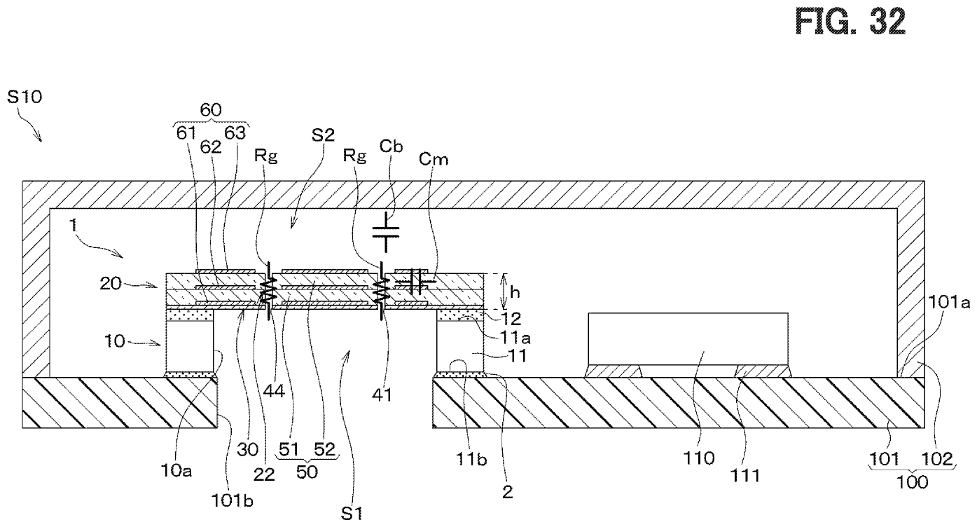

The piezoelectric device S10 of the present embodiment is basically the same as that of the first embodiment and has a configuration as illustrated in FIG. 32. The piezoelectric element 1 in FIG. 32 corresponds to the piezoelectric element 1 in FIG. 1C. FIG. 32 schematically illustrates an acoustic resistance Rg and the like to be described later. In this case, the sensitivity in the piezoelectric device S10 is represented by 1/{(1/Cm)+(1/Cb)}, where the acoustic compliance of the piezoelectric element 1 is Cm and the acoustic compliance of the back space S2 is Cb. The acoustic compliance Cb is expressed by the following Mathematical Formula 2.

$$Cb = \frac{Vb}{p 0 \times {c}^{2}} \qquad ( Mathematical Formula 2 )$$

In Mathematical Formula 2, Vb is the volume of the back space S2, ρ0 is the air density, and c is the sound speed. The acoustic compliance Cb is proportional to the volume Vb of the back space S2. Thus, the influence of the acoustic compliance Cb on the sensitivity decreases as the back space S2 decreases. At present, it is desired to downsize the piezoelectric device S10, and the back space S2 is also reduced by downsizing the piezoelectric device S10. Thus, the sensitivity of the piezoelectric device S10 is greatly affected by the acoustic compliance Cm of the piezoelectric element 1.

In the first embodiment, the frequency at which the sensitivity can be maintained is widened by increasing the resonance frequency of the piezoelectric element 1. In this case, the target frequency at which the sensitivity can be maintained can also be widened by reducing the low-frequency roll-off frequency. Thus, in the present embodiment, the low-frequency roll-off frequency is reduced.

The low-frequency roll-off frequency fr is expressed by the following Mathematical Formula 3, where Rg is the acoustic resistance (that is, air resistance) caused by the slit 40 (that is, the first to fourth slits 41 to 44).

$$fr = \frac{1}{2 π \times Rg \times Cb} \qquad ( Mathematical Formula 3 )$$

Thus, the acoustic resistance Rg or the acoustic compliance Cb of the back space S2 may be increased to reduce the low-frequency roll-off frequency fr. However, the acoustic compliance Cb is proportional to the volume Vb of the back space S2 as in Mathematical Formula 2. At present, it is desired to downsize the piezoelectric device S10. Thus, it is preferable to increase the acoustic resistance Rg to reduce the low-frequency roll-off frequency fr. The acoustic resistance Rg is expressed by the following Mathematical Formula 4.

$$R g = \frac{3 \times μ \times h}{\sqrt{2} \times {g}^{3} \times L} \qquad ( Mathematical Formula 4 )$$

In Mathematical Formula 4, μ is the frictional resistance of air, h is the thickness of the vibration region 22, g is the slit width g of the slit 40, and L is the slit length L of the slit 40 in each vibration region 22. In the present embodiment, the slit widths g of the first to fourth slits 41 to 44 are equal to each other, and the slit lengths L of the first to fourth slits 41 to 44 are equal to each other.

The following Mathematical Formula 5 may be satisfied to set the low-frequency roll-off frequency fr to 20 Hz or less, which is outside the audible range.

$$fr = \frac{1}{2 π \times Rg \times Cb} \leq 20 ( Hz ) \qquad ( Mathematical Formula 5 )$$

In this case, the following Mathematical Formula 6 is obtained by changing Mathematical Formula 5. When Mathematical Formula 6 is changed based on Mathematical Formula 4, the following Mathematical Formula 7 is obtained.

$$\begin{matrix}R g \geq \frac{1}{20 \times 2 π \times Cb} = \frac{1}{40 π \times Cb} & ( Mathematical Formula 6 ) \\ L \leq \frac{3 \times μ \times h \times 40 π \times Cb}{\sqrt{2} \times {g}^{3}} & ( Mathematical Formula 7 )\end{matrix}$$

Thus, the slit length L, the slit width g, the thickness h of the vibration region 22, and the acoustic compliance Cb of the back space S2 may be formed to satisfy Mathematical Formula 7 to set the low-frequency roll-off frequency fr to 20 Hz or less. In the present embodiment, the slit length L is adjusted to satisfy Mathematical Formula 7.

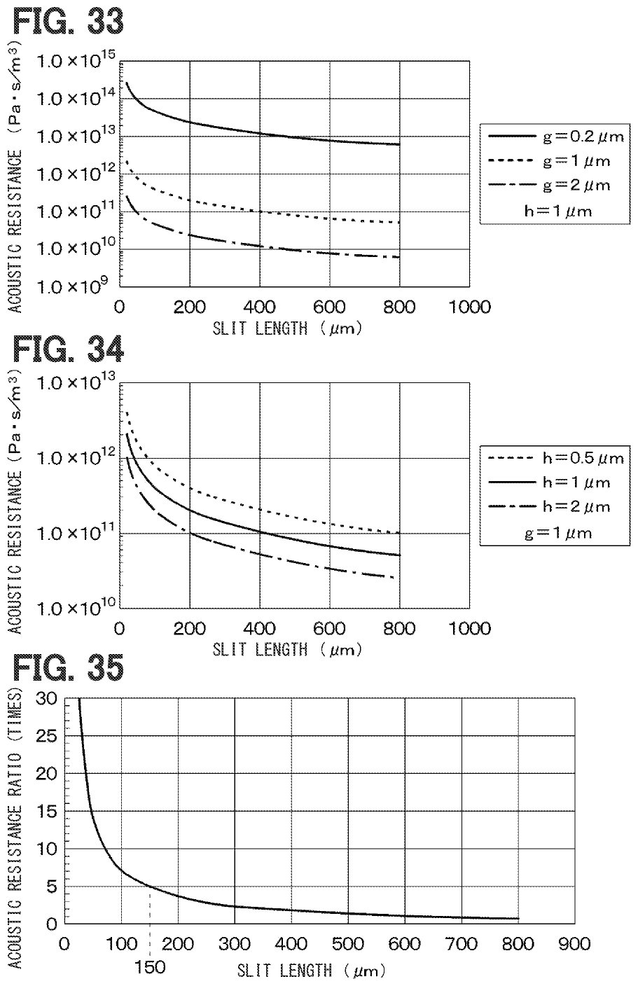

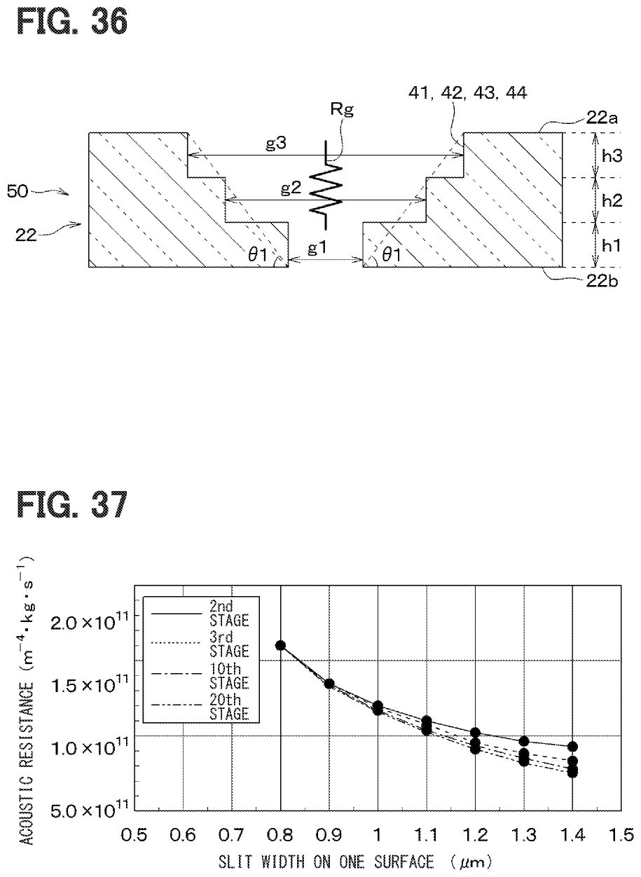

Here, for example, when the thickness h of the vibration region 22 is 1 μm, it is confirmed that the acoustic resistance Rg decreases as the slit width g increases, and the acoustic resistance Rg decreases as the slit length L increases, as shown in FIG. 33. When the slit width g is 1 μm, it is confirmed that the acoustic resistance Rg decreases as the thickness h of the vibration region 22 increases, and the acoustic resistance Rg decreases as the slit length L increases, as shown in FIG. 34. Then, as shown in FIG. 35, for example, based on the case where the slit length L with the acoustic resistance of about 100 Hz is 700 μm, it is confirmed that the slit length L may be 20 Hz or less when the slit length L is about 150 μm.

In FIG. 35, since the case where the slit length L is 700 μm is used as a reference, the acoustic resistance ratio in the case where the slit length L is 700 μm is 1. In FIG. 35, the volume of the back space S2 that affects the acoustic compliance Cb of the back space S2 is 4×10⁻⁹ m³.

According to the present embodiment described above, the vibration region 22 is supported at both ends. Thus, the resonance frequency f of the piezoelectric element 1 can be increased, and the same effect as in the first embodiment can be obtained.
(1) In the present embodiment, the slit length L, the slit width g, the thickness h of the vibration region 22, and the acoustic compliance Cb of the back space S2 are formed to satisfy Mathematical Formula 7. Thus, the low-frequency roll-off frequency fr can be set to 20 Hz or less, and the range in which the sensitivity can be maintained can be widened.

### Ninth Embodiment

A ninth embodiment will be described. The present embodiment is different from the eighth embodiment in the shape of the slit 40. The other configurations are the same as those of the eighth embodiment, and thus the description thereof is omitted here.

In the eighth embodiment, the configuration in which the slit width g is constant along the thickness direction of the vibration region 22 has been described. However, the slit 40 may have a shape in which the slit width g changes along the thickness direction of the vibration region 22, and for example, the slit width g may change in three stages as illustrated in FIG. 36. Specifically, in the present embodiment, the slit 40 (that is, the first to fourth slits 41 to 44) is formed such that the slit width g increases in the order of g1, g2, and g3 from the other surface 22b side of the vibration region 22 toward the one surface 22a side.

In this case, the slit length L is expressed by the following Mathematical Formula 8. In the following Mathematical Formula 8, h1 is the thickness of the vibration region 22 where the slit width is g1 in the vibration region 22, h2 is the thickness of the vibration region 22 where the slit width is g2 in the vibration region 22, and h3 is the thickness of the vibration region 22 where the slit width is g3 in the vibration region 22.

$$\begin{matrix}L \leq \frac{3 \times μ \times h 1 \times 40 π \times Cb}{\sqrt{2} \times g {1}^{3}} + \frac{3 \times μ \times h 2 \times 40 π \times Cb}{\sqrt{2} \times g {2}^{3}} + \frac{3 \times μ \times h 3 \times 40 π \times Cb}{\sqrt{2} \times g {3}^{3}} & \end{matrix} \qquad ( Mathematical Formula 8 )$$

When the width of the slit 40 on the other surface 22b side is g1 and the width on the one surface 22a side is g3, the acoustic resistance Rg is as shown in FIG. 37 with change in the number of stages between the other surface 22b and the one surface 22a. Specifically, when the slit width g1 on the other surface 22b side and the slit width g3 on the one surface 22a side are the same, it is confirmed that the acoustic resistance Rg tends to increase on the side having a smaller number of the stages. The low-frequency roll-off frequency fr decreases as the acoustic resistance Rg increases, from Mathematical Formula 3. Thus, when the slit width g of the slit 40 is changed along the thickness direction of the vibration region 22, it is preferable to adjust the number of stages in consideration of the acoustic compliance Cb of the back space S2. FIG. 37 is a diagram in a case where the slit width g1 on the other surface 22b side is 0.8 μm, the entire thickness h of the vibration region 22 is 1 μm, and the slit width g3 on the one surface 22a side is changed.

According to the present embodiment described above, the vibration region 22 is supported at both ends. Thus, the resonance frequency f of the piezoelectric element 1 can be increased, and the same effect as in the first embodiment can be obtained.
(1) As in the present embodiment, the slit 40 does not have to have a constant slit width g along the thickness direction of the vibration region 22.

### Modification of Ninth Embodiment

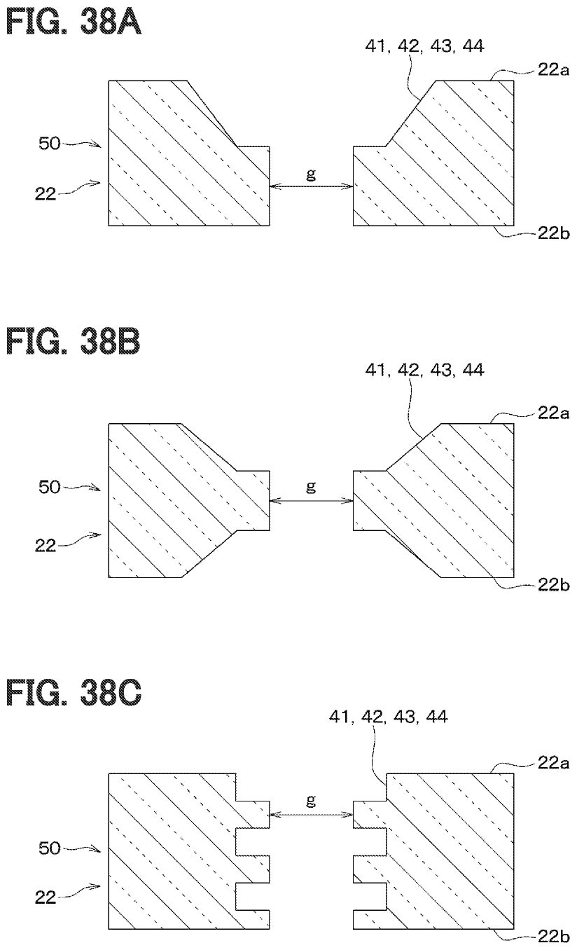

A modification of a tenth embodiment will be described. In the tenth embodiment, the shape of the slit 40 (that is, the first to fourth slits 41 to 44) may be changed as appropriate. For example, as illustrated in FIG. 38A, the first to fourth slits 41 to 44 may have a tapered shape in which the slit width g on the other surface 22b side is constant and the slit width g on the one surface 22a side gradually increases. As illustrated in FIG. 38B, the first to fourth slits 41 to 44 may be configured such that the slit width g at the central portion of the vibration region 22 in the thickness direction is the narrowest. As illustrated in FIG. 38 C, in the first to fourth slits 41 to 44, a portion having a narrow slit width g and a portion having a wide slit width g of the vibration region 22 may be alternately formed in the thickness direction of the vibration region 22.

### Tenth Embodiment

A tenth embodiment will be described. In the present embodiment, the shape of the bonding member 2 is defined with respect to the first embodiment. The other configurations are the same as those of the first embodiment, and thus the description thereof is omitted here.

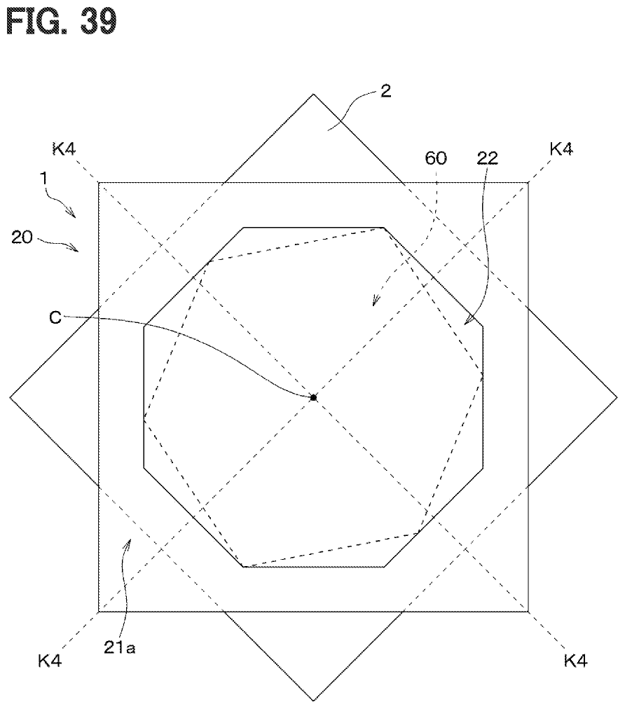

In the piezoelectric device S10 of the present embodiment, as illustrated in FIG. 39, the bonding member 2 has a rectangular outer shape having corners in the normal direction. The bonding member 2 is bonded to a portion different from a portion to be a corner of the piezoelectric element 1 on the other surface 11b of the support substrate 11 in the piezoelectric element 1. In the present embodiment, the bonding member 2 is disposed such that the corners of the bonding member 2 respectively protrude from opposing sides of the piezoelectric element 1 in the normal direction. The bonding member 2 is disposed such that each corner of the bonding member 2 is positioned at a portion different from the portion on the virtual line K4 connecting the opposite corners in the outer shape of the piezoelectric element 1. The bonding member 2 of the present embodiment is configured using a bonding sheet whose outer shape is defined in advance.

In the present embodiment, the electrode film 60 has a hexagonal shape, and the vibration region 22 has a regular octagonal shape as in the sixth embodiment. The electrode film 60 and the vibration region 22 are disposed to be symmetric with respect to the center C. In FIG. 39, the slit 40 is omitted.

According to the present embodiment described above, the vibration region 22 is supported at both ends. Thus, the resonance frequency f of the piezoelectric element 1 can be increased, and the same effect as in the first embodiment can be obtained.
(1) In the present embodiment, the bonding member 2 is disposed at a portion different from the corners of the outer shape of the piezoelectric element 1. Thus, propagation of the thermal stress from the printed circuit board 101 to the corners of the piezoelectric element 1 where the deformation tends to be large can be prevented. Thus, the piezoelectric element 1 is hardly deformed by the propagated thermal stress, and the vibration region 22 is hardly deformed. As a result, deterioration in the detection sensitivity can be prevented, and the detection accuracy can improve.
(2) In the present embodiment, the bonding member 2 has a rectangular outer shape having corners. The bonding member 2 is disposed such that each corner is positioned at a portion different from the portion on the virtual line K4 in the normal direction. Thus, stress concentration in the corners of the bonding member 2 due to deformation of the piezoelectric element 1 can be prevented, and occurrence of a defect such as peeling of the bonding member 2 can be prevented.

### Modification of Tenth Embodiment

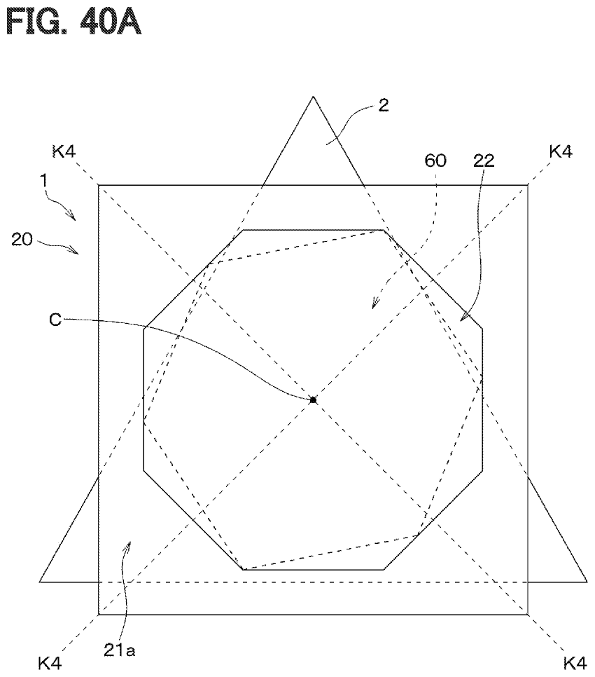

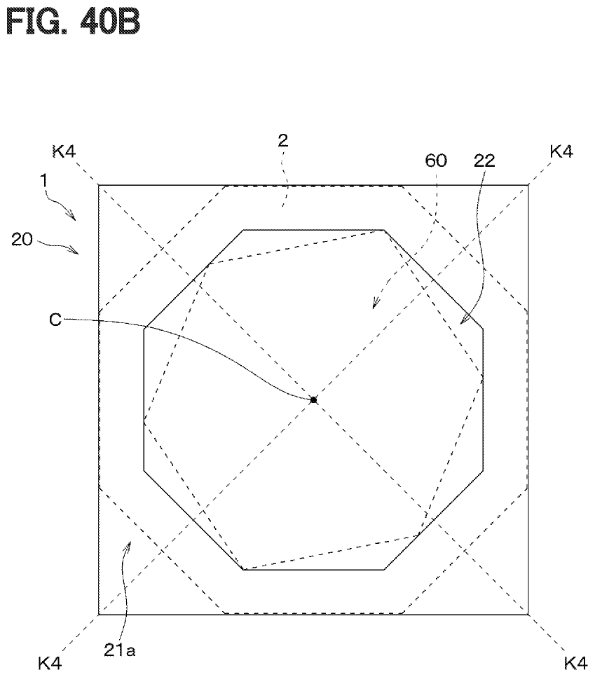

A modification of a tenth embodiment will be described. The bonding member 2 may have an equilateral triangular shape in the normal direction as illustrated in FIG. 40A or may have a regular octagonal shape in the normal direction as illustrated in FIG. 40B. Although not illustrated, the bonding member 2 may have a regular hexagonal shape, a regular decagonal shape, or the like in the normal direction. The bonding member 2 may be disposed to protrude from the piezoelectric element 1 in the normal direction or may be disposed only inside the piezoelectric element 1.

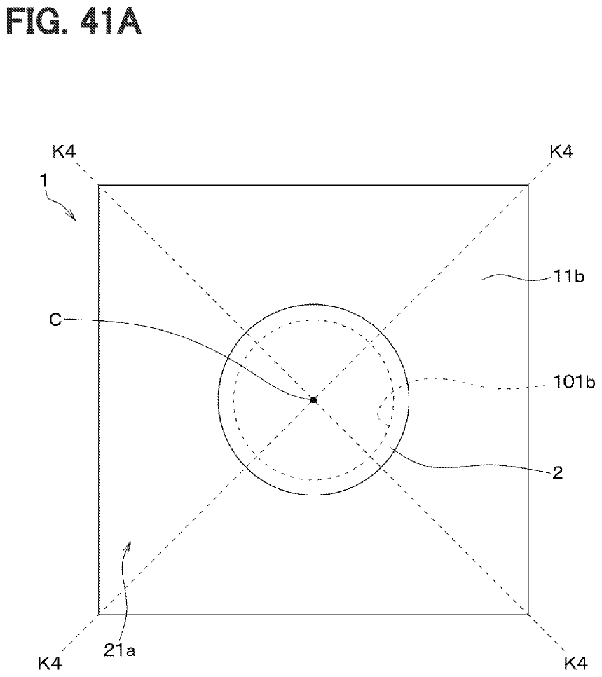

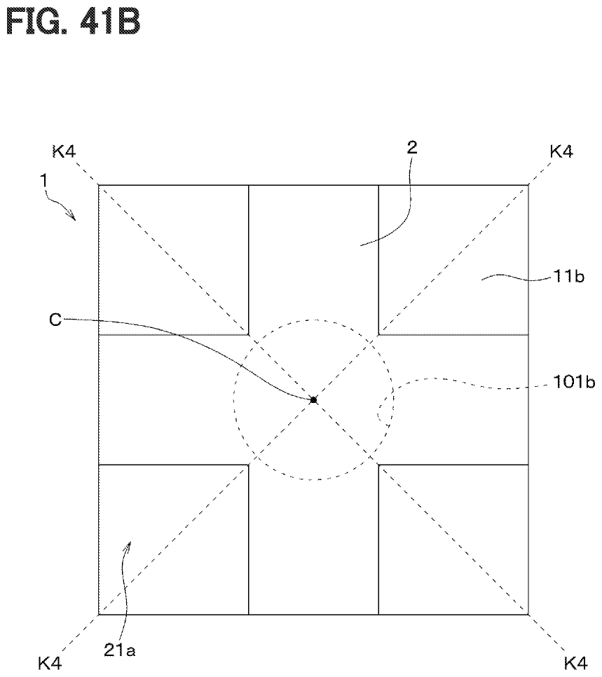

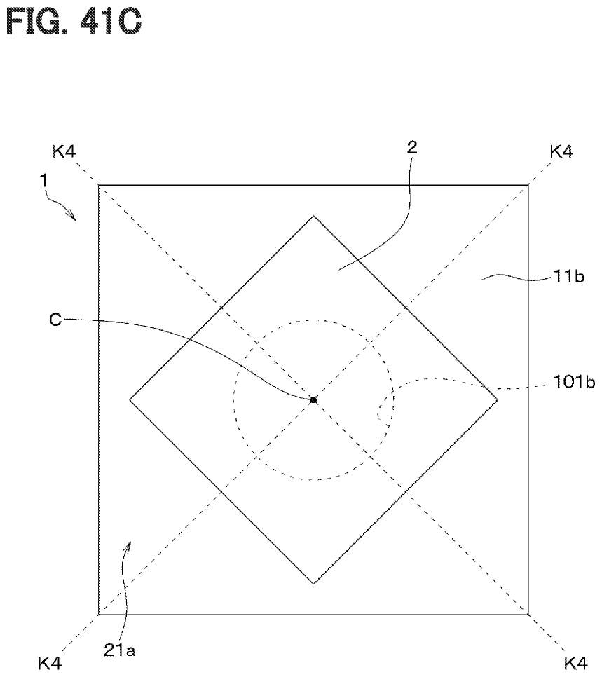

The bonding member 2 may be disposed as illustrated in FIGS. 41A to 41C with reference to the through hole 101b formed in the printed circuit board 101. FIGS. 41A to 41C are plan views of the piezoelectric element 1 and the bonding member 2 as viewed from the other surface 11b side of the support substrate 11. In FIGS. 41A to 41C, the vibration region 22 is omitted, and a portion facing the through hole 101b is indicated by a broken line. In FIGS. 41A to 41C, the recess 10a formed in the support substrate 11 has a shape that matches up with the through hole 101b in the normal direction.

For example, as illustrated in FIG. 41A, the bonding member 2 may have an annular shape surrounding the through hole 101b in the normal direction. As illustrated in FIG. 41B, the bonding member 2 may have the shape of a cross having a portion extending in one direction and a portion orthogonal to the one direction in the normal direction. As illustrated in FIG. 41C, the bonding member 2 may have a rhombus shape in the normal direction. In FIG. 41B, the corners of the bonding member 2 are positioned on the virtual line K4. However, even with such a configuration, since the bonding member 2 is bonded only to a portion different from the corners of the piezoelectric element 1, thermal stress is hardly propagated to the corners of the piezoelectric element 1, and the same effect as that of the above-described tenth embodiment can be obtained.

### Eleventh Embodiment

An eleventh embodiment will be described. The present embodiment is different from the first embodiment in that a protrusion is formed on the printed circuit board 101. The other configurations are the same as those of the first embodiment, and thus the description thereof is omitted here.

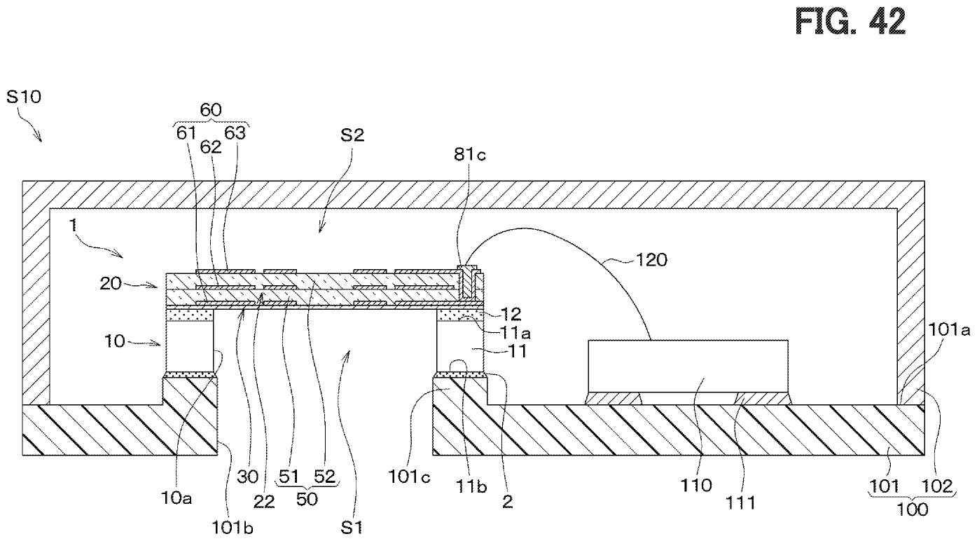

In the piezoelectric device S10 of the present embodiment, a protrusion 101c is formed on the printed circuit board 101 as illustrated in FIG. 42. Specifically, the protrusion 101c has a shape conforming to the outer shape of the bonding member 2 and is formed of a part of the printed circuit board 101. For example, the protrusion 101c of the present embodiment is formed in a portion of the printed circuit board 101 facing the piezoelectric element 1, the portion being different from a portion facing the corners of the piezoelectric element 1.

According to the present embodiment described above, the vibration region 22 is supported at both ends. Thus, the resonance frequency f of the piezoelectric element 1 can be increased, and the same effect as in the first embodiment can be obtained.
(1) In the present embodiment, the protrusion 101c is formed on the printed circuit board 101. Thus, when the bonding member 2 in a liquid form is applied and disposed, the outer shape of the bonding member 2 to be bonded to the piezoelectric element 1 can be easily adjusted by applying the bonding member 2 on the protrusion 101c. Thus, a liquid form can be used for the bonding member 2, and the selectivity of the bonding member 2 can improve. In particular, when the shape of the bonding member 2 is adjusted as in the above-described tenth embodiment, the outer shape of the bonding member 2 can be easily adjusted.

### Modification of Eleventh Embodiment

A modification of the eleventh embodiment will be described. In the eleventh embodiment, the protrusion 101c may be configured as a separate member from the printed circuit board 101.

### Twelfth Embodiment

A twelfth embodiment will be described. The present embodiment is different from the first embodiment in the shape of the slit 40. The other configurations are the same as those of the first embodiment, and thus the description thereof is omitted here.

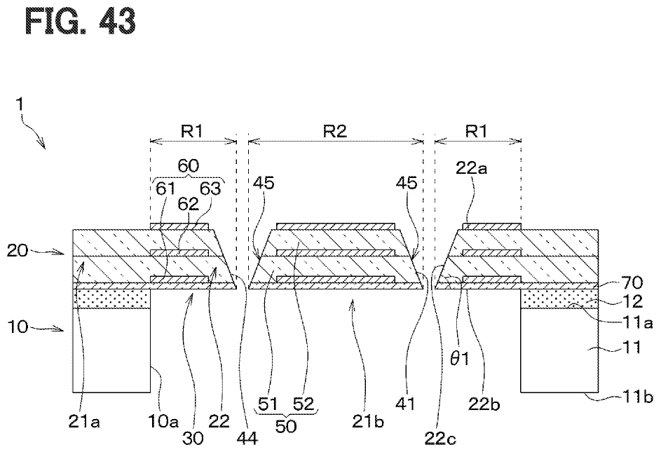

In the piezoelectric element 1 of the present embodiment, the piezoelectric film 50 is made of ScAlN. As illustrated in FIG. 43, the first slit 41 and the fourth slit 44 form a tapered portion 45 whose width decreases from the one surface 22a side toward the other surface 22b side. In other words, the first slit 41 and the fourth slit 44 are formed such that the side surface 22c is the tapered portion 45. The first slit 41 and the fourth slit 44 of the present embodiment have a shape in which the width continuously decreases from the one surface 22a side toward the other surface 22b side. That is, the first slit 41 is formed such that the side surface 22c of the vibration region 22 is substantially planar.

The first slit 41 and the fourth slit 44 are formed such that an angle θ1 formed by the other surface 22b and the side surface 22c in the vibration region 22 (hereinafter, also simply referred to as an angle formed by the vibration region 22) is 39 to 81°.

The formed angle θ1 may also be referred to as a tapered angle of the slit 40. The second slit 42 and the third slit 43 have the same shape as the first slit 41 and the fourth slit 44 in a cross section different from FIG. 43. FIG. 43 corresponds to a cross-sectional view taken along line IC-IC in FIG. 2A. In the vibration region 22, the one surface 22a and the other surface 22b are parallel to each other. In the present embodiment, the other surface 22b corresponds to a surface parallel to the one surface 22a.

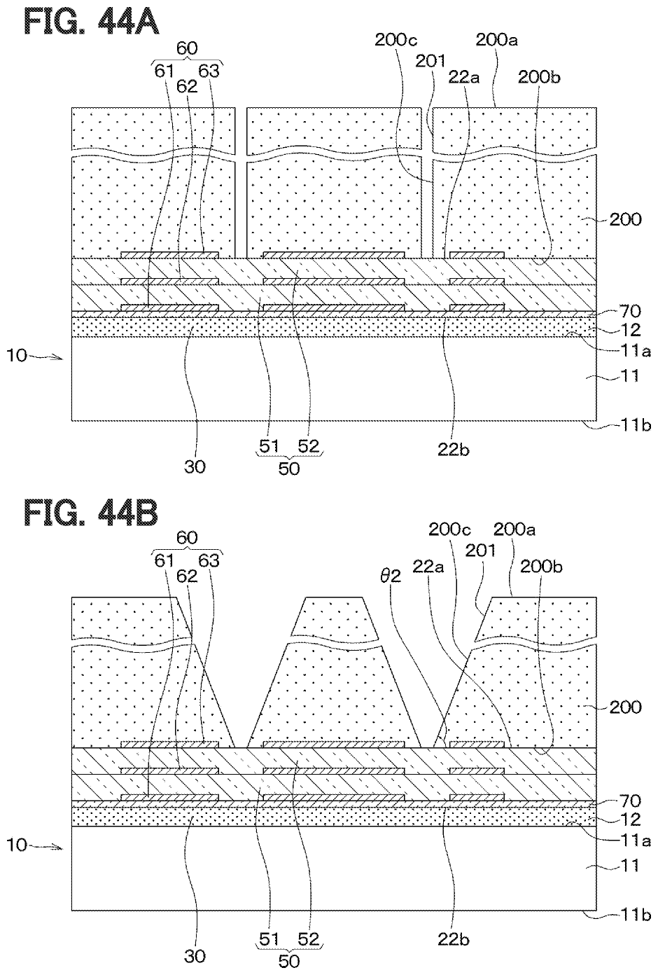

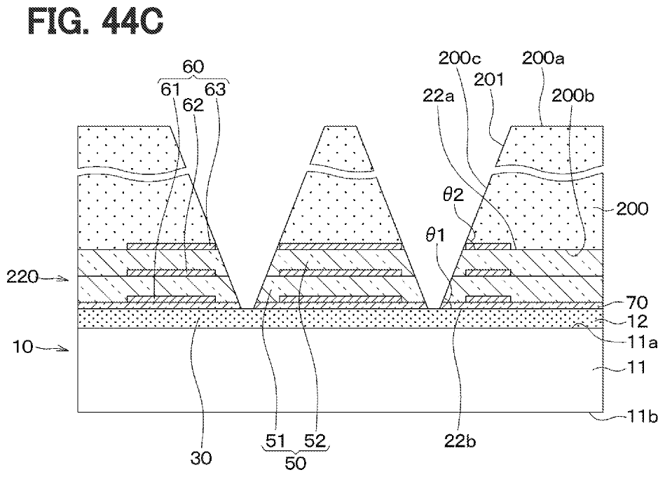

Next, a method for manufacturing the piezoelectric element 1 will be described with reference to FIGS. 44A to 44C, 45, and 46. FIGS. 44A to 44C correspond to a cross-sectional view taken along line IC-IC in FIG. 2A. FIGS. 44A to 44C illustrate cross-sectional views of the first slit 41 and the fourth slit 44, but the same applies to the second and third slits 42 and 43.

First, the same step as in FIG. 4A is performed to prepare a material in which the first to fourth slits 41 to 44 are not formed.

Subsequently, as illustrated in FIG. 44A, an etching mask material 200 formed of a photoresist or the like is disposed to cover the upper electrode film 63 or the like, and an opening 201 in which a portion where the first to fourth slits 41 to 44 are to be formed is opened is formed in the etching mask material 200. The second and third slits 42 and 43 are formed in a cross section different from FIG. 44A. Hereinafter, the surface of the etching mask material 200 on the side covering the upper electrode film 63 and the upper piezoelectric film 52 is referred to as other surface 200b, the opposite surface of the etching mask material 200 from the other surface 200b is referred to as one surface 200a, and a side surface of the opening 201 is referred to as a side surface 200c.

Next, as illustrated in FIG. 44B, the shape of the opening 201 of the etching mask material 200 is adjusted by performing a heat treatment. Specifically, the etching mask material 200 is disposed to cover the upper electrode film 63 and the upper piezoelectric film 52, and the portion on the other surface 200b side fixed to these films and the portion on the one surface 200a side are different from each other in the manner of thermal shrinkage. More specifically, when a heat treatment is performed, the portion of the etching mask material 200 on the other surface 200b side is less likely to thermally shrink, and the portion on the one surface 200a side is likely to thermally shrink. Thus, by performing a heat treatment, an angle θ2 formed by the other surface 200b and the side surface 200c of the etching mask material 200 (hereinafter, also simply referred to as an angle θ2 formed by the etching mask material 200) is adjusted in accordance with a desired angle θ1 formed by the vibration region 22. In this case, since the piezoelectric film 50 and the etching mask material 200 are made of different materials, the etching rates when anisotropic dry etching described later is performed are usually different. Thus, based on the etching rate and the like, the angle θ2 formed by the etching mask material 200 is adjusted so that the angle θ1 formed by the vibration region 22 becomes a desired value. The angle θ2 formed by the etching mask material 200 here is adjusted as described above, and thus it may match up with the angle θ1 formed by the vibration region 22 in some cases, but it does not match up with the angle θ1 formed by the vibration region 22 in some cases.

Next, as illustrated in FIG. 44C, anisotropic dry etching is performed using the etching mask material 200 as a mask to form the first to fourth slits 41 to 44 that penetrate the piezoelectric film 50 and reach the support 10. In the present embodiment, the first to fourth slits 41 to 44 are formed so as to constitute the vibration region constituent part 220 having the side surface 22c to be the tapered portion 45.

At this time, as described above, the angle θ2 formed by the etching mask material 200 is adjusted according to the angle θ1 formed by the vibration region 22, and the angle θ1 formed by the vibration region constituent part 220 is 39 to 81° . The vibration region constituent part 220 is a portion to be the vibration region 22 with the formation of the recess 10a. Thus, the angle θ1 formed by the vibration region constituent part 220 and the angle θ1 formed by the vibration region 22 are the same. In the drawing, one surface, the other surface, and the side surface of the vibration region constituent part 220 are denoted by the same reference numerals as the one surface 22a, the other surface 22b, and the side surface 22c of the vibration region 22. The shapes of the lower electrode film 61, the intermediate electrode film 62, and the upper electrode film 63 are adjusted so as not to reach the first to fourth slits 41 to 44. Thus, in this step, the piezoelectric film 50 and the base film 70 are subjected to anisotropic dry etching.

Thereafter, the same step as in FIG. 4C is performed, and etching is performed to penetrate the insulating film 12 from the other surface 11 b of the support substrate 11 and reach the base film 70, whereby the recess 10a is formed. As a result, the vibration region constituent part 220 floats from the support 10 to form the vibration region 22, and the piezoelectric element 1 illustrated in FIG. 1 is manufactured.

Next, the angle θ1 formed by the vibration region constituent part 220 (that is, the vibration region 22) in the manufacturing process of the present embodiment will be described.

First, according to the study of the inventors of the present invention, the following phenomenon has been confirmed when the formed angle θ1 is 81° or more in a case where anisotropic dry etching is performed on the piezoelectric film 50 made of ScAlN or the like. That is, it has been confirmed that when the formed angle θ1 is 81° or more, processability tends to decrease because of the influence of redeposition, in which etched atoms are redeposited on the side surface 22c of the first to fourth slits 41 to 44. Further, according to the study of the inventors of the present invention, the following phenomenon has been confirmed when the formed angle θ1 is 63° or more in a case where anisotropic dry etching is performed on the piezoelectric film 50 made of ScAlN or the like. That is, it has been confirmed that when the formed angle θ1 is 63° or more, processability tends to decrease because of the influence of a fence formed of etched atoms redeposited in the vicinity of the opening on the one surface 22a side of the first to fourth slits 41 to 44. Thus, when the first to fourth slits 41 to 44 are formed, the formed angle θ1 is preferably 63° or less. As a result, deterioration in the processability due to the fence or the like can be prevented.

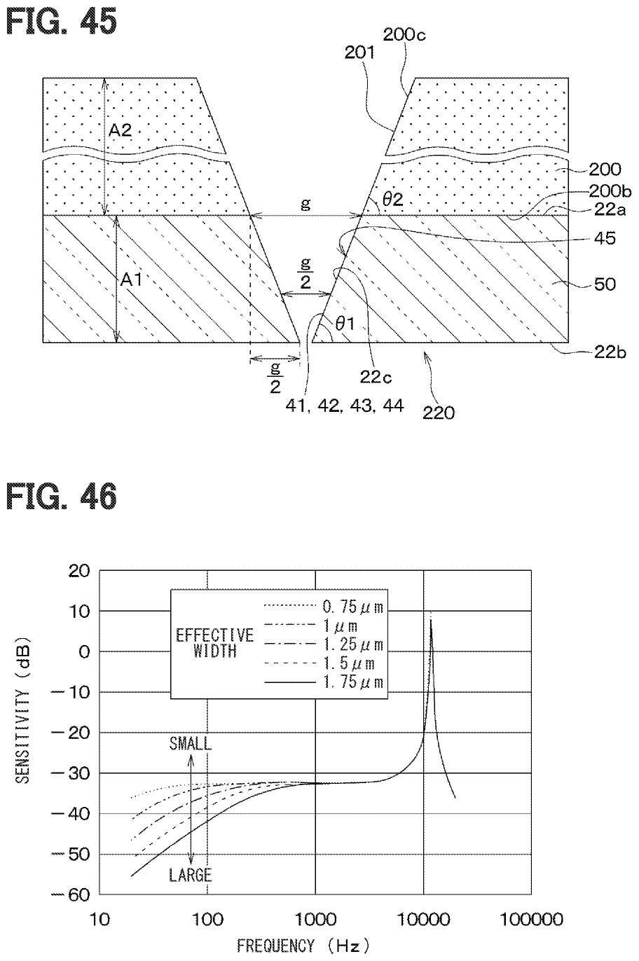

Further, ScAlN constituting the piezoelectric film 50 is a difficult-to-etch material. According to the study of the inventors of the present invention, it has been confirmed that the film thickness of the etching mask material 200 is preferably 1 to 5 times the film thickness of the piezoelectric film 50 to make the etching mask material 200 to remain on the piezoelectric film 50 in the case of forming the first to fourth slits 41 to 44 penetrating the piezoelectric film 50. In other words, in the case of forming the first to fourth slits 41 to 44 penetrating the piezoelectric film 50, it has been confirmed that the film thickness of the etching mask material 200 is preferably 1 to 5 times the film thickness of the piezoelectric film 50 to prevent the piezoelectric film 50 covered with the etching mask material 200 from being removed by anisotropic dry etching. That is, as illustrated in FIG. 45, when the film thickness of the piezoelectric film 50 is A1, the film thickness A2 of the etching mask material 200 is preferably A1 to 5A1. As described above, the base film 70 of the present embodiment is formed extremely thin with respect to the piezoelectric film 50. Thus, the influence of the base film 70 is ignored. In other words, the film thickness A1 of the piezoelectric film 50 corresponds to the thickness h of the vibration region 22.

The first to fourth slits 41 to 44 are also subjected to the influence of exposure restrictions of the processing device when formed. According to the study by the inventors of the present invention, when the width of the first to fourth slits 41 to 44 on the one surface 22a side is the slit width g as illustrated in FIG. 45, it has been confirmed that the resolution of the slit width g with respect to the film thickness A2 of the etching mask material 200 is limited to ½ to ⅓ of the film thickness A2 of the etching mask material 200 in a current typical processing device. Thus, since the film thickness A2 of the etching mask material 200 is indicated by A1 to 5A1, the slit width g is limited to the range of A1/3 to 5A1/2.

In the piezoelectric element 1 as described above, sound pressure is released from the first to fourth slits 41 to 44. In this case, as illustrated in FIG. 46, the sensitivity at a low frequency decreases as the effective width of the first to fourth slits 41 to 44 increases. Thus, the first to fourth slits 41 to 44 are preferably formed to have a narrow effective width. The effective widths of the first to fourth slits 41 to 44 are average widths of the first to fourth slits 41 to 44. For example, when the first to fourth slits 41 to 44 have a tapered shape in which the slit width g continuously decreases from the one surface 22a toward the other surface 22b as in the present embodiment, the effective width is the average of the width on the one surface 22a side and the width on the other surface 22b side.

Since the first to fourth slits 41 to 44 of the present embodiment are formed by anisotropic dry etching, the side surface 22c has a substantially planar shape. Thus, when the width of the first to fourth slits 41 to 44 on the other surface 22b side is assumed to be substantially 0 to prevent deterioration in the sensitivity, tan θ1=A1/(g/2) is obtained where A1 is the film pressure of the piezoelectric film 50, and g is the slit width on the one surface 22a side. Note that g/2 may also be referred to as an effective slit width. Thus, since the slit width g is A1/3 to 5A1/2 as described above, tan θ1=6 to 0.8, and θ1=39 to 81° are preferable. That is, when the first to fourth slits 41 to 44 are formed, the angle θ1 formed by the vibration region constituent part 220 is preferably set to 39 to 81° . As a result, deterioration in the processability of the first to fourth slits 41 to 44 due to the film thickness A2 of the etching mask material 200 can be prevented.

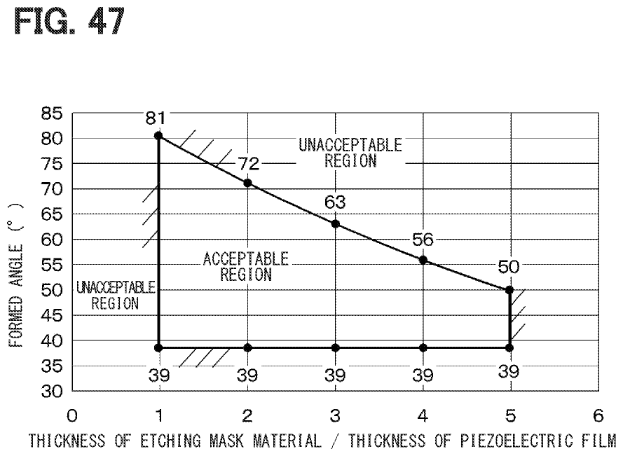

The relationship between the ratio of the film thickness A2 of the etching mask material 200 to the film thickness A1 of the piezoelectric film 50 (hereinafter, also referred to as a film thickness ratio) and the formed angle is summarized as shown in FIG. 47. As described above, the resolution of the slit width g with respect to the film thickness A2 of the etching mask material 200 is limited to ½ to ⅓ of the film thickness A2 of the etching mask material 200. Thus, the formed angle θ1 takes 39°, which is the lower limit, when the resolution is ½ times the resolution of the etching mask material 200 and takes the upper limit when the resolution is ⅓ times the resolution of the etching mask material.

Here, as the piezoelectric element 1 of a comparative example, a piezoelectric element is taken in which the piezoelectric film 50 is made of a material to be easily etched, such as AlN, and the side surface 22c of the vibration region 22 is substantially perpendicular to the other surface 22b. The effective width of the slit 40 in the piezoelectric element 1 of the comparative example is set to g. In this case, when the effective width in the piezoelectric element 1 of the present embodiment is g or more, the slit width g of the first to fourth slits 41 to 44 is excessively increased, and the sensitivity may be lower than that of the piezoelectric element 1 of the comparative example.

Thus, the slit 40 is preferably to have an effective width equal to or less than the effective width of the slit 40 in the piezoelectric element 1 of the comparative example. That is, it is preferable that tan θ1 is set to 1 or more. Thus, θ1 is preferably 45° or more. As a result, deterioration in the sensitivity can also be prevented. In this case, deterioration in the processability of the slit 40 due to a fence or the like can also be prevented by setting θ1 to 63° or less.

According to the present embodiment described above, the vibration region 22 is supported at both ends. Thus, the resonance frequency f of the piezoelectric element 1 can be increased, and the same effect as in the first embodiment can be obtained.
(1) In the present embodiment, the angle θ1 formed by the vibration region 22 is 39 to 81°. Thus, deterioration in the processability of the slit 40 due to the film thickness A2 of the etching mask material 200 can be prevented, and the slit 40 can be suitably formed. In addition, since the formed angle θ1 is 81° or less, the influence of redeposition can be reduced, and deterioration in the processability can be prevented.
(2) In the present embodiment, since the angle θ formed by the vibration region 22 is 63° or less, deterioration in the processability due to the influence of the fence can be further prevented.
(3) In the present embodiment, since the angle θ1 formed by the vibration region 22 is 45° or more, deterioration in the detection sensitivity can be further prevented.

The present embodiment can also be applied to a case where the slit 40 is formed in a stepwise manner along the thickness direction of the vibration region 22 as in the ninth embodiment. In this case, as illustrated in FIG. 36, the angle θ1 may be an angle formed between a line connecting the opening end of the slit 40 on the other surface 22b side and the opening end of the slit 40 on the one surface 22a side and the other surface 22b.

When the electrode film slit 60b is formed in the electrode film 60 as in the sixth embodiment, the slit 40 is formed every time the piezoelectric films 51 and 52 are formed. Thus, in this configuration, the angle θ1 may be an angle between the portion of each of the piezoelectric films 51 and 52 on the other surface 20b side and the side surface 20c.

### Modification of Twelfth Embodiment

A modification of the twelfth embodiment will be described. In the twelfth embodiment, when the first slits 41 to 44 are formed, dry etching may be performed after wet etching is performed. According to this, since the etching mask material 200 is not removed when wet etching is performed, the film thickness A2 of the etching mask material 200 defined based on the film thickness A1 of the piezoelectric film 50 can be reduced, and the slit width g defined by the film thickness A2 of the etching mask material 200 can be decreased. Thus, the effective width g/2 can be decreased, and the sensitivity can be improved.

### Other Embodiments

Although the present disclosure has been described in accordance with the embodiments, it is understood that the present disclosure is not limited to the embodiments and structures. The present disclosure also includes various modifications and modifications within an equivalent range. In addition, various combinations and modes, and other combinations and modes including only one element, more elements, or less elements are also within the scope and idea of the present disclosure.

For example, in each of the above embodiments, the vibration unit 20 may include at least one piezoelectric film 50 and one electrode film 60. The planar shape of the piezoelectric element 1 does not have to be a rectangular shape but may be a polygonal shape, such as a pentagonal shape or a hexagonal shape.

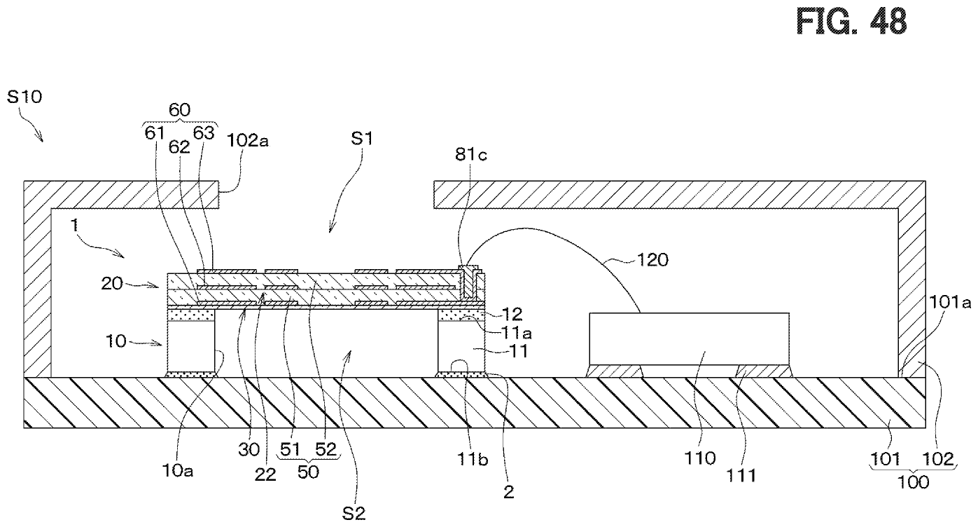

In each of the above embodiments, the piezoelectric device S10 may have a configuration in which a through hole 102a is formed in the lid 102 as illustrated in FIG. 48. In this case, as illustrated in FIG. 48, the pressure receiving surface space S1 is a space on the one surface 22a side in the vibration region 22 of the casing 100, and the back space S2 is a space on the other surface 22b side in the vibration region 22 of the casing 100.

In each of the above embodiments, the piezoelectric element 1 has been described in which the detection accuracy is improved by supporting the vibration region 22 at both ends. However, in the second embodiment for example, the detection accuracy can be improved by forming the slit 40 in a tapered shape. In the sixth embodiment, the detection accuracy can be improved by the shapes of the piezoelectric film 50 and the electrode film 60. In the seventh embodiment, the detection accuracy can be improved by the positional relationship between the slit 40 and the through hole 101b. In the eighth embodiment, the detection accuracy of the piezoelectric element 1 can be improved by reducing the low-frequency roll-off frequency. In the tenth embodiment, the detection accuracy can be improved by the positional relationship between the piezoelectric element 1 and the bonding member 2. Thus, in the piezoelectric element 1 or the piezoelectric device S10, the vibration region 22 may be cantilevered. That is, for example, when the outer shape of the vibration region 22 is a rectangular shape in a plane and the first to fourth slits 41 to 44 are formed in the vibration region 22, the first to fourth slits 41 to 44 may be formed to intersect at the center C of the vibration region 22. Since the manufacturing method in the twelfth embodiment relates to the shape of the slit 40, the manufacturing method can also be applied to a method of manufacturing the piezoelectric element 1 in which the vibration region 22 is cantilevered.

The above embodiments can be appropriately combined. For example, the second embodiment may be combined with the third to twelfth embodiments, and the slit 40 may have a tapered shape in which the width is decreased toward the center C. The third embodiment may be combined with the fourth to twelfth embodiments, and charges may be extracted also from the center region 225 of the vibration region 22. The fourth embodiment or the fifth embodiment may be combined with the sixth to twelfth embodiments, and the vibration region 22 may be supported at both ends by the coupling member 90 or the coupling member 91. The sixth embodiment may be combined with the seventh to twelfth embodiments, and the shape and disposition of the vibration region 22 and the electrode film 60 may be defined. The seventh embodiment may be combined with the eighth to twelfth embodiments, and the slit 40 may be formed in a portion different from the portion facing the through hole 101b. The eighth embodiment may be combined with the ninth to twelfth embodiments, and the slit length L may be defined. The ninth embodiment may be combined with the tenth to twelfth embodiments, and the slit width g of the slit 40 may be changed along the thickness direction of the vibration region 22. The tenth embodiment may be combined with the eleventh and twelfth embodiments, and the positioning of the bonding member 2 may be defined. The eleventh embodiment may be combined with the twelfth embodiment, and the protrusion 101c may be formed on the printed circuit board 101. Combinations of the above embodiments may be further combined.

What is claimed is:

1. A piezoelectric element comprising:
a support; and
a vibration unit disposed on the support, the vibration unit including a piezoelectric film, and an electrode film that is connected to the piezoelectric film to extract charges generated by a deformation of the piezoelectric film, the vibration unit having a support region supported by the support, and a vibration region connected to the support region and floating from the support, and the vibration unit being configured to output a pressure detection signal based on the charges, wherein
the vibration region includes a plurality of slits extending from a support region side toward a center of the vibration region, and the vibration region is supported at both ends with respect to the support region.

2. The piezoelectric element according to claim 1, wherein
the vibration region has a resonance frequency of 20 kHz or more.

3. The piezoelectric element according to claim 1, wherein
the plurality of slits are extended from the support region side and are terminated on the support region side of the vibration region closer to the support region than the center of the vibration region.

4. The piezoelectric element according to claim 1, wherein
at least some of the plurality of slits have different slit lengths along an extending direction of the slits.

5. The piezoelectric element according to claim 1, wherein
the plurality of slits have a tapered shape in which a slit width is decreased from the support region side toward the center.

6. The piezoelectric element according to claim 1, wherein
the plurality of slits intersect each other at the center, and
a coupling member is embedded in a portion where the plurality of slits intersect each other.

7. The piezoelectric element according to claim 1, wherein
the plurality of slits intersect each other at the center, and
a coupling member that covers a portion where the plurality of slits intersect each other is disposed on one surface of the vibration region, the one surface being on an opposite side from the support.

8. The piezoelectric element according to claim 6, wherein
the coupling member has a rigidity equal to or lower than a rigidity of a material constituting the piezoelectric film.

9. The piezoelectric element according to claim 1, wherein
in the vibration region, a region on the support region side and a region including the center are defined as a first region, and a region different from the first region is defined as a second region, and
the electrode film is disposed at least in the first region.

10. The piezoelectric element according to claim 1, wherein
the vibration region and the electrode film are disposed in a state of being symmetric with respect to the center of the vibration region in a normal direction with respect to one surface of the vibration region, the one surface being on an opposite side from the support.

11. The piezoelectric element according to claim 10, wherein
in the vibration region, a region on the support region side and a region including the center are defined as a first region, and a region different from the first region is defined as a second region,
the piezoelectric film is made of a material having a hexagonal crystal structure, and
the electrode film is divided by six electrode film slits, and, in the normal direction, a virtual shape connecting predetermined portions in the respective electrode film slits in the first region is a hexagonal shape.

12. The piezoelectric element according to claim 10, wherein
the support includes a support substrate, an insulating film that is disposed on the support substrate and on which the vibration unit is disposed, and a recess that causes the vibration region to float, the recess being formed in the support substrate and the insulating film,
the support substrate is formed of a silicon substrate, and
the vibration region has a regular octagonal outer shape in the normal direction.

13. The piezoelectric element according to claim 1, wherein
the vibration unit has a polygonal outer shape in a normal direction with respect to one surface of the vibration region, the one surface being on an opposite side from the support, and
at least one of the electrode film and the vibration region has a polygonal shape with corners in the normal direction, and each of the corners is positioned at a portion different from a portion on a virtual line connecting opposite corners of the outer shape of the vibration unit.

14. The piezoelectric element according to claim 1, wherein
the piezoelectric film is made of scandium aluminum nitride,
each of the slits is formed in a state where a tapered portion whose width decreases from one surface side, which is on a side opposite from the support, toward another surface side, the other surface side being opposite to the one surface in the vibration region is formed, and
the electrode film is disposed on an inner side from the slit in a normal direction with respect to the one surface, and
an angle formed by a side surface constituting the tapered portion in the vibration region and the surface parallel to the one surface is 39 to 81°.

15. The piezoelectric element according to claim 14, wherein
the angle formed by the side surface constituting the tapered portion and the surface parallel to the one surface is 63° or less.

16. The piezoelectric element according to claim 14, wherein
the angle formed by the side surface constituting the tapered portion and the surface parallel to the one surface is 45° or more.

17. The piezoelectric element according to claim 6, wherein
the coupling member is solid.

18. A piezoelectric device including a piezoelectric element, the piezoelectric element including a vibration unit that outputs a pressure detection signal according to a pressure, the piezoelectric device comprising:
the piezoelectric element according to claim 1; and
a casing including a mounted member on which the piezoelectric element is mounted and a lid fixed to the mounted member with the piezoelectric element being accommodated, the casing having a through hole communicating with an outside and through which the pressure is introduced.

19. The piezoelectric device according to claim 18, wherein
each of the slits is formed in a portion different from a portion facing the through hole in the vibration region.

20. The piezoelectric device according to claim 18, wherein below:
each of the slits has a slit length satisfying a mathematical formula shown
$$L \leq \frac{3 \times μ \times h \times 40 π \times Cb}{\sqrt{2} \times {g}^{3}}$$
wherein a space different from a pressure receiving surface space positioned between the through hole and the vibration unit in the space in the casing is a back space, and wherein Cb is an acoustic compliance of the back space, h is a thickness of the vibration region, g is a slit width of the slit, μ is an air resistance, and L is the slit length of the slit.

21. The piezoelectric device according to claim 18, wherein
in the piezoelectric element, the support is mounted on the mounted member with a bonding member interposed between the support and the mounted member, and the piezoelectric element has a polygonal outer shape with corners in a normal direction with respect to one surface of the vibration region, the one surface being on the opposite side from the support, and
the bonding member is disposed at a portion different from the corners in the normal direction.

22. The piezoelectric device according to claim 21, wherein
the bonding member has a polygonal outer shape with corners in the normal direction, and each of the corners is positioned at a portion different from a portion on a virtual line connecting opposite corners of the outer shape of the piezoelectric element.

23. The piezoelectric device according to claim 21, wherein
the mounted member includes a protrusion formed at a portion where the bonding member is disposed, and
the bonding member is disposed on the protrusion.

24. A method for manufacturing a piezoelectric element,
the piezoelectric element including:
a support; and
a vibration unit disposed on the support, the vibration unit including a piezoelectric film, an electrode film that is connected to the piezoelectric film and extracts charges generated by a deformation of the piezoelectric film, the vibration unit having a support region supported by the support, and a vibration region connected to the support region and floating from the support, and the vibration unit configured to output a pressure detection signal based on the charges, wherein
the vibration region includes a plurality of slits formed from the support region side toward a center of the vibration region, and
the vibration region is supported at both ends with respect to the support region,
the method comprising:
providing the support;
forming the piezoelectric film and the electrode film on the support;
disposing an etching mask material on the piezoelectric film and the electrode film, and forming an opening in the etching mask material to expose a portion of the piezoelectric film where each of the slits is to be formed;
forming the slits by performing etching with the etching mask material used as a mask, so that each of the slits penetrates the piezoelectric film, reaches the support, and defines a vibration region constituent part having a tapered portion where a width of a side surface exposed from the slit is decreased from one surface side, which is on an opposite side from the support side, toward another surface side opposite to the one surface; and
forming a recess from the opposite side of the support from the piezoelectric film to cause the vibration region constituent part to float, thereby to constitute the vibration unit including the vibration region,
wherein
in the forming of the piezoelectric film and the electrode film, the piezoelectric film and the electrode film are formed such that only the piezoelectric film is exposed from the side surface when the vibration region constituent part is formed, and
in the forming of the slits, the slits are formed in which an angle formed by a side surface constituting the tapered portion and the surface parallel to the one surface is 39 to 81°.

25. The method for manufacturing a piezoelectric element according to claim 24, wherein
in the forming of the slits, the slits having the formed angle of 63° or less are formed.

26. The method for manufacturing a piezoelectric element according to claim 24, wherein
in the forming of the slits, the slits having the formed angle of 45° or more are formed.
